(19) United States
(12) Patent Application Publication
(10) Pub. No.: US 2026/0107658 A1
(43) Pub. Date: Apr. 16, 2026

(54) DISPLAY PANEL AND DISPLAY APPARATUS

(71) Applicant: BOE Technology Group Co., Ltd., Beijing (CN)

(72) Inventors: Lixia QIU, Beijing (CN); Haiyan SUN, Beijing (CN); Dan WANG, Beijing (CN); Haidong WU, Beijing (CN); Tong WU, Beijing (CN)

(73) Assignee: BOE Technology Group Co., Ltd., Beijing (CN)

(21) Appl. No.: 19/114,746

(22) PCT Filed: May 24, 2024
(86) PCT No.: PCT/CN2024/095283

§ 371 Date: Mar. 24, 2025

(30) Foreign Application Priority Data
Jun. 29, 2023 (CN) 202310787250.3

(51) Int. Cl. H10K 59/00; H10K 50/17; H10K 59/122; H10K 59/35; H10K 85/60

(52) U.S. Cl. CPC H10K 59/771; H10K 59/122; H10K 59/353; H10K 85/633; H10K 85/636; H10K 50/17; H10K 85/615; H10K 85/626; H10K 85/6572; H10K 85/6574; H10K 85/6576

(57) ABSTRACT

The present disclosure belongs to the technical field of display. Disclosed are a display panel and a display apparatus. The display panel comprises a driving backplane, a pixel electrode layer, a light-emitting functional layer and a common electrode layer, which are sequentially arranged in a stacked manner, wherein the light-emitting functional layer has common material layers, which cover gaps between a plurality of light-emitting elements; and at least one of the common material layers contains a hole-transport-type nitrogen-containing compound, and the hole-transport-type nitrogen-containing compound has relatively high transverse resistance after becoming a film. The display panel can reduce the crosstalk between light-emitting elements.

### CROSS-REFERENCE TO RELATED APPLICATIONS

The present disclosure is a U.S. National Stage Application of International Application No. PCT/CN2024/095283, filed on May 24, 2024, which is based upon and claims priority to Chinese patent application number 202310787250.3, filed on Jun. 29, 2023, and entitled “Display Panel and Display Apparatus”, the entire contents of each are incorporated herein by reference.

### TECHNICAL FIELD

The present disclosure relates to the field of display technology, and in particular, to a display panel and a display apparatus.

### BACKGROUND

Self-luminescence display technologies such as OLED (Organic Light-Emitting Diode) and QLED (Quantum Dot Light-Emitting Diode) have advantages such as wide color gamut, fast response speed, wide viewing angles, and foldability, making them increasingly popular in various display products. In some display products, different sub-pixels share common material layers, which can lead to crosstalk between them.

It should be noted that the information disclosed in the Background section above is only for enhancing the understanding of the background of the present disclosure, and thus may include information that does not constitute prior art known to those of ordinary skill in the art.

### SUMMARY

An object of the present disclosure is to provide a display panel and a display apparatus that reduce crosstalk between light-emitting elements.

According to one aspect of the present disclosure, a display panel is provided, including a driving backplane, a pixel electrode layer, a light-emitting functional layer, and a common electrode layer stacked in sequence. The light-emitting functional layer includes a common material layer that covers the gaps between a plurality of light-emitting elements. At least one of the common material layers includes a hole-transport-type nitrogen-containing compound, the structural formula of which is shown in Chemical Formula 1:

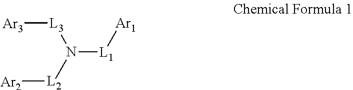

wherein, L₁, L₂, L₃ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
Ar₁ to Ar₃ are each independently selected from a substituted or unsubstituted aryl with 6 to 50 ring carbon atoms, a substituted or unsubstituted heteroaryl with 5 to 40 ring carbon atoms, and —N(Ar₄Ar₅); Ara and Ar₅ are each independently selected from a substituted or unsubstituted aryl with 6 to 50 ring carbon atoms, a substituted or unsubstituted heteroaryl with 5 to 40 ring carbon atoms; wherein at least one of Ar₁ to Ar₃ contains a benzopentacyclic fragment or a dithiophene fragment;
when L₁, L₂, L₃, Ar₁, Ar₂, Ar₃, Ar₄ or Ar₅ has a substituent, the substituent is selected from deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms.

According to an embodiment of the present disclosure, at least one of Ar₁ to Ar₃ has a group shown in the following Chemical Formula 2 or Chemical Formula 3:

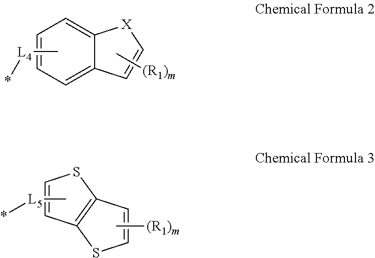

wherein, * indicates connection with L₁, L₂, L₃ or N;
L₄, L₅ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
X is selected from N(R₂), C(R₃R₄), O, S, Si (R₃R₄); m is 0, 1 or 2;
R₁ is selected from the group consisting of deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms;
R₂ to R₄ are each independently selected from a substituted or unsubstituted alkyl with 1 to 10 carbon atoms, a substituted or unsubstituted cycloalkyl with 5 to 10 carbon atoms, a substituted or unsubstituted aryl with 6 to 30 carbon atoms, or a substituted or unsubstituted heteroaryl with 5 to 30 carbon atoms;
when the number of R₁ is two, the two R₁ can also be connected to each other to form an aromatic ring or an aliphatic ring;
R₃ and R₄ can also be connected to each other to form an aromatic ring or an aliphatic ring.

According to an embodiment of the present disclosure, the L₁, L₂ and L₃ are each independently selected from a single bond, a phenylene, a biphenylene, a terphenylene, a naphthylene, and a trimphenylene;
Ar₁ to Ar₅ are each independently selected from 9,9′-dimethylfluorenyl, spirofluorenyl, benzothiophenyl, N-phenylcarbazolyl, phenyl, biphenyl, 9-phenyl-1,2,3,4-tetrabydrocarbazolyl, phenyl-substituted thieno[3,2-b]thienyl, thieno[3,2-b]thienyl, naphthyl, 9,9′-diphenylfluorenyl, dibenzofuranyl, dibenzothienyl, and at least one of Ar₁ to Ar₃ contains phenyl-substituted thieno[3,2-b]thienyl or thieno[3,2-b]thienyl.

According to an embodiment of the present disclosure, the hole-transport-type nitrogen-containing compound is selected from the group consisting of the following compounds:

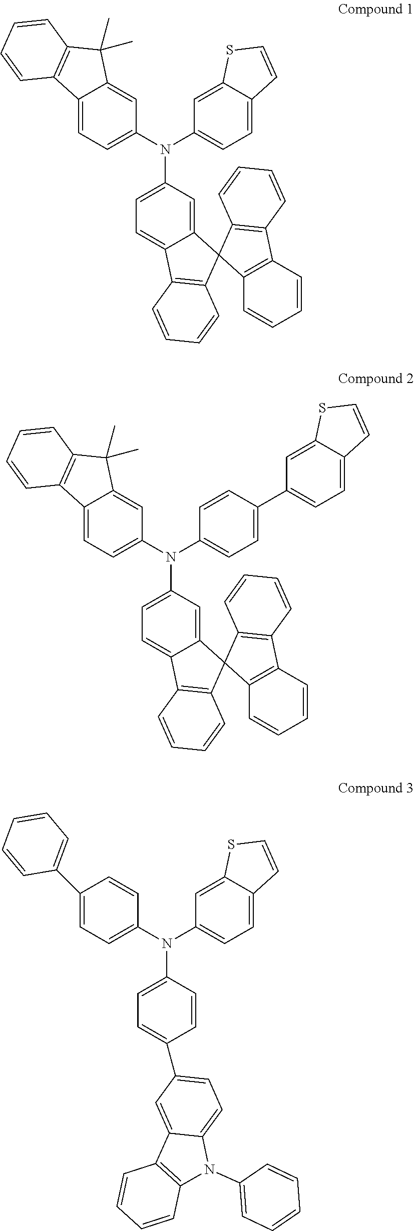 [SMILES: CC1(C)c2ccccc2-c2ccc(N(c3ccc4c(c3)C3(c5ccccc5-c5ccccc53)c3ccccc3-4)c3ccc4ccsc4c3)cc21 ; CC1(C)c2ccccc2-c2ccc(N(c3ccc(-c4ccc5ccsc5c4)cc3)c3ccc4c(c3)C3(c5ccccc5-c5ccccc53)c3ccccc3-4)cc21 ; c1ccc(-c2ccc(N(c3ccc(-c4ccc5c(c4)c4ccccc4n5-c4ccccc4)cc3)c3ccc4ccsc4c3)cc2)cc1]

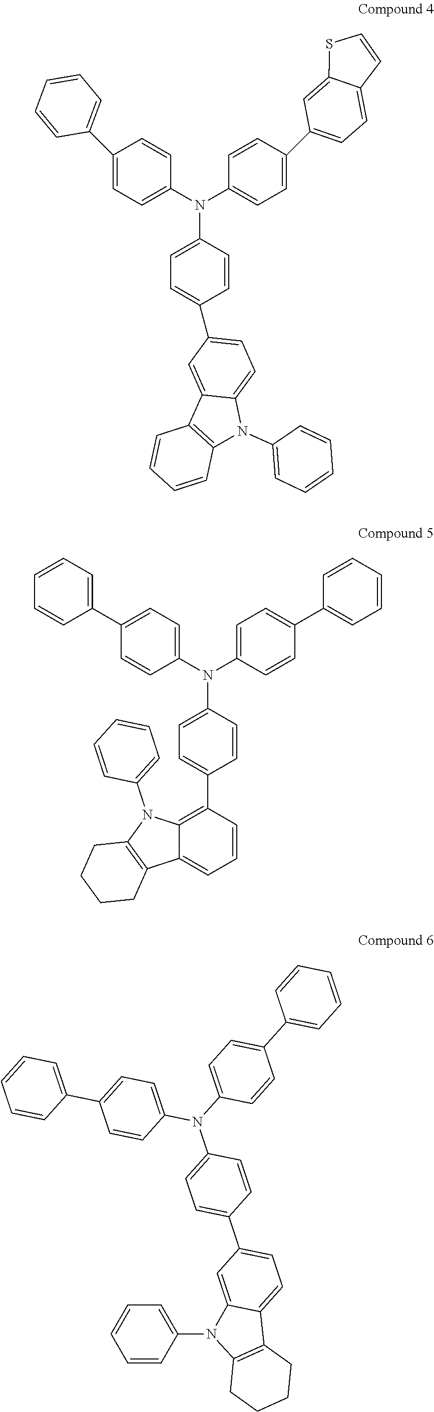 [SMILES: c1ccc(-c2ccc(N(c3ccc(-c4ccc5ccsc5c4)cc3)c3ccc(-c4ccc5c(c4)c4ccccc4n5-c4ccccc4)cc3)cc2)cc1 ; c1ccc(-c2ccc(N(c3ccc(-c4ccccc4)cc3)c3ccc(-c4cccc5c6c(n(-c7ccccc7)c45)CCCC6)cc3)cc2)cc1 ; c1ccc(-c2ccc(N(c3ccc(-c4ccccc4)cc3)c3ccc(-c4ccc5c6c(n(-c7ccccc7)c5c4)CCCC6)cc3)cc2)cc1]

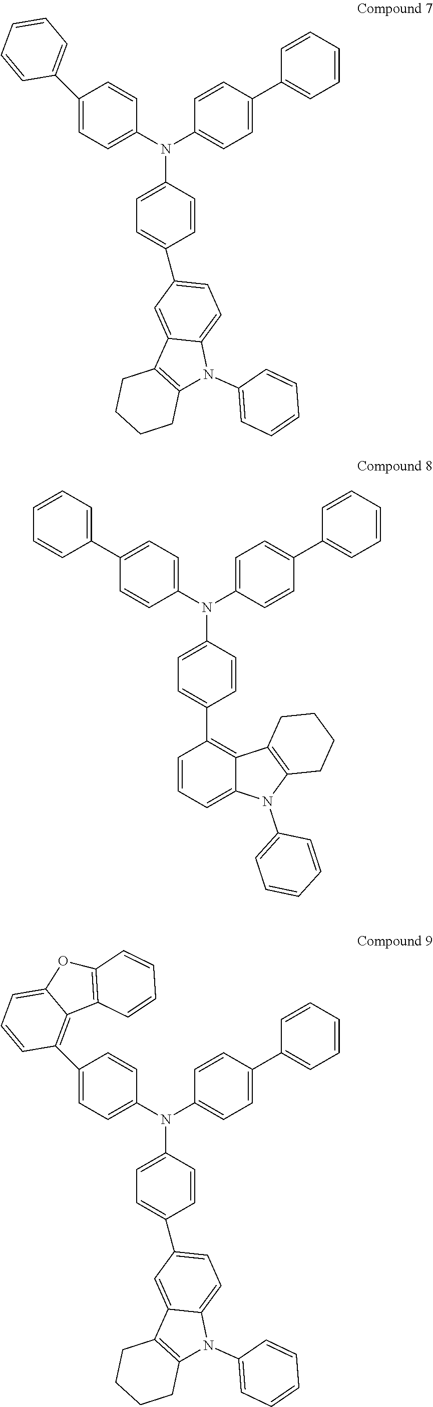 [SMILES: c1ccc(-c2ccc(N(c3ccc(-c4ccccc4)cc3)c3ccc(-c4ccc5c(c4)c4c(n5-c5ccccc5)CCCC4)cc3)cc2)cc1 ; c1ccc(-c2ccc(N(c3ccc(-c4ccccc4)cc3)c3ccc(-c4cccc5c4c4c(n5-c5ccccc5)CCCC4)cc3)cc2)cc1 ; c1ccc(-c2ccc(N(c3ccc(-c4ccc5c(c4)c4c(n5-c5ccccc5)CCCC4)cc3)c3ccc(-c4cccc5oc6ccccc6c45)cc3)cc2)cc1]

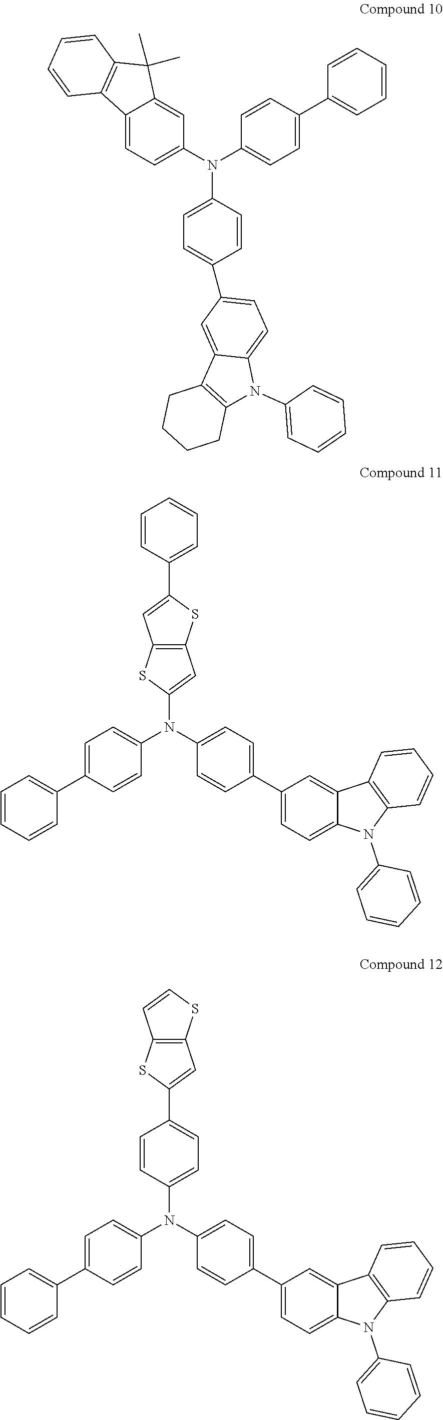 [SMILES: CC1(C)c2ccccc2-c2ccc(N(c3ccc(-c4ccccc4)cc3)c3ccc(-c4ccc5c(c4)c4c(n5-c5ccccc5)CCCC4)cc3)cc21 ; c1ccc(-c2ccc(N(c3ccc(-c4ccc5c(c4)c4ccccc4n5-c4ccccc4)cc3)c3cc4sc(-c5ccccc5)cc4s3)cc2)cc1 ; c1ccc(-c2ccc(N(c3ccc(-c4ccc5c(c4)c4ccccc4n5-c4ccccc4)cc3)c3ccc(-c4cc5sccc5s4)cc3)cc2)cc1]

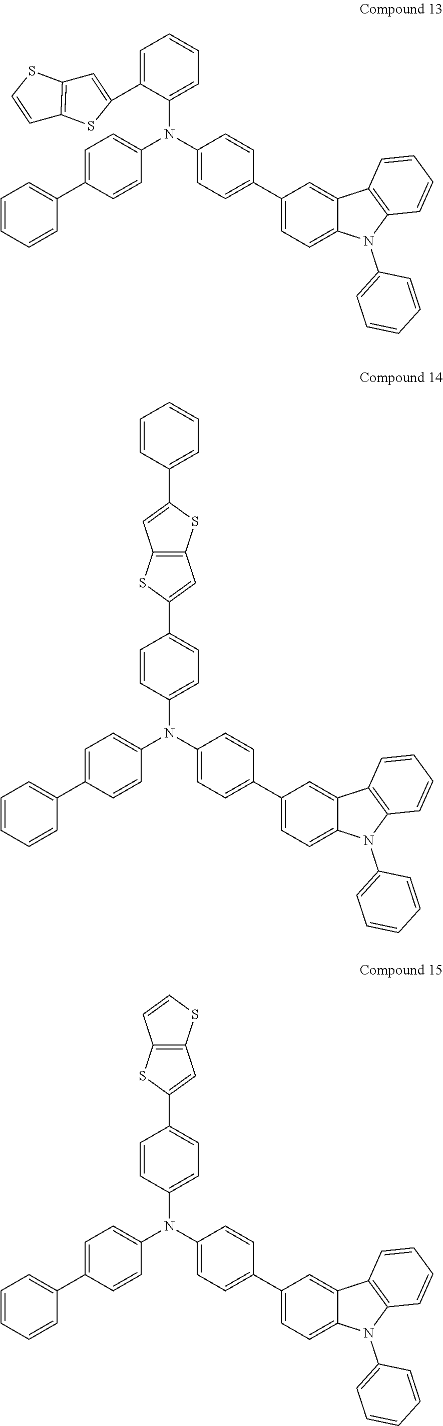 [SMILES: c1ccc(-c2ccc(N(c3ccc(-c4ccc5c(c4)c4ccccc4n5-c4ccccc4)cc3)c3ccccc3-c3cc4sccc4s3)cc2)cc1 ; c1ccc(-c2ccc(N(c3ccc(-c4ccc5c(c4)c4ccccc4n5-c4ccccc4)cc3)c3ccc(-c4cc5sc(-c6ccccc6)cc5s4)cc3)cc2)cc1 ; c1ccc(-c2ccc(N(c3ccc(-c4ccc5c(c4)c4ccccc4n5-c4ccccc4)cc3)c3ccc(-c4cc5sccc5s4)cc3)cc2)cc1]

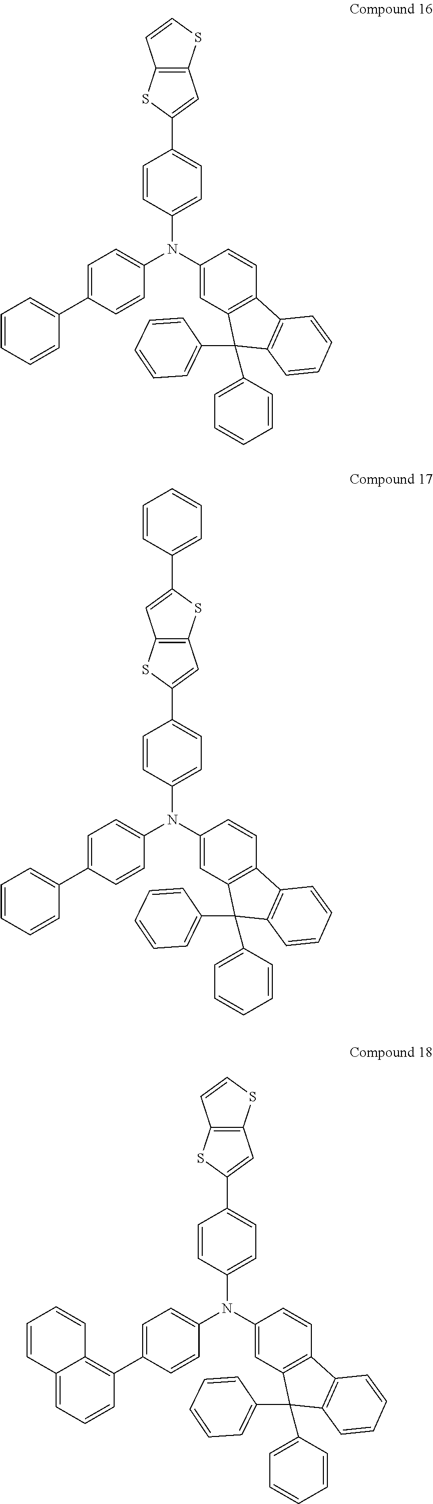 [SMILES: c1ccc(-c2ccc(N(c3ccc(-c4cc5sccc5s4)cc3)c3ccc4c(c3)C(c3ccccc3)(c3ccccc3)c3ccccc3-4)cc2)cc1 ; c1ccc(-c2ccc(N(c3ccc(-c4cc5sc(-c6ccccc6)cc5s4)cc3)c3ccc4c(c3)C(c3ccccc3)(c3ccccc3)c3ccccc3-4)cc2)cc1 ; c1ccc(C2(c3ccccc3)c3ccccc3-c3ccc(N(c4ccc(-c5cc6sccc6s5)cc4)c4ccc(-c5cccc6ccccc56)cc4)cc32)cc1]

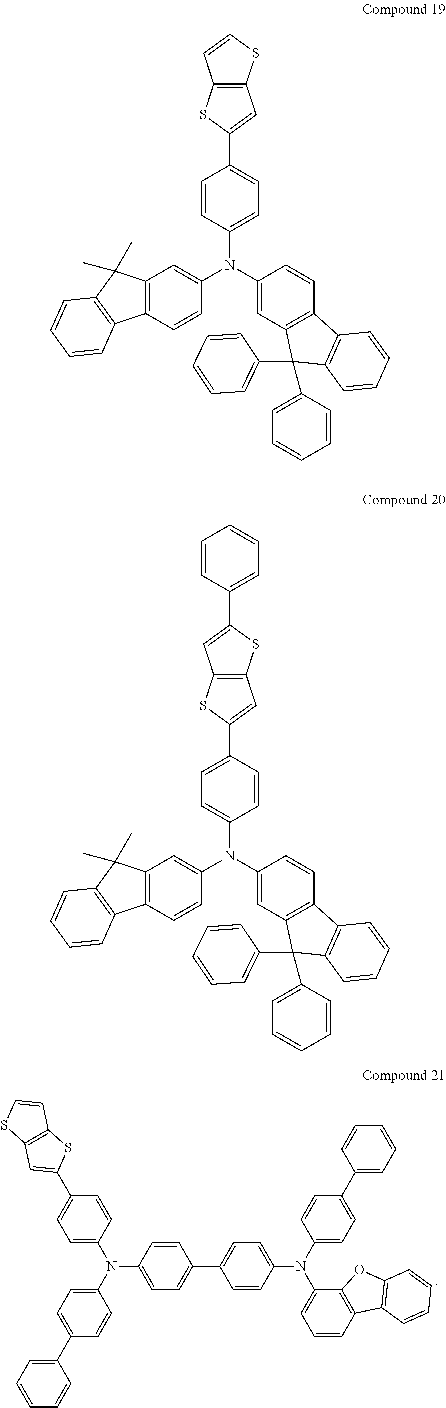 [SMILES: CC1(C)c2ccccc2-c2ccc(N(c3ccc(-c4cc5sccc5s4)cc3)c3ccc4c(c3)C(c3ccccc3)(c3ccccc3)c3ccccc3-4)cc21 ; CC1(C)c2ccccc2-c2ccc(N(c3ccc(-c4cc5sc(-c6ccccc6)cc5s4)cc3)c3ccc4c(c3)C(c3ccccc3)(c3ccccc3)c3ccccc3-4)cc21 ; c1ccc(-c2ccc(N(c3ccc(-c4ccc(N(c5ccc(-c6ccccc6)cc5)c5cccc6c5oc5ccccc56)cc4)cc3)c3ccc(-c4cc5sccc5s4)cc3)cc2)cc1]

According to an embodiment of the present disclosure, the light-emitting functional layer includes a hole injection material layer; the hole injection material layer covers the gaps between the plurality of light-emitting elements and includes the hole-transport-type nitrogen-containing compound.

According to an embodiment of the present disclosure, the material of the hole injection material layer consists of the hole-transport-type nitrogen-containing compound and a P-type dopant, and the mass content of the P-type dopant does not exceed 3%.

According to an embodiment of the present disclosure, the material of the hole injection material layer consists of the hole-transport-type nitrogen-containing compound and a P-type dopant, and the mass content of the P-type dopant is between 0.5% and 1.5%.

According to an embodiment of the present disclosure, the light-emitting functional layer includes a P-type charge generation material layer, which covers the gaps between the plurality of light-emitting elements and includes the hole-transport-type nitrogen-containing compound.

According to an embodiment of the present disclosure, the material of the P-type charge generation material layer consists of the hole-transport-type nitrogen-containing compound and a P-type dopant, and the mass content of the P-type dopant is not less than 10%.

According to an embodiment of the present disclosure, the material of the P-type charge generation material layer consists of the hole-transport-type nitrogen-containing compound and a P-type dopant, and the mass content of the P-type dopant is between 10% and 15%.

According to an embodiment of the present disclosure, the light-emitting functional layer includes an N-type charge generation material layer, and the N-type charge generation material layer covers the gaps between the plurality of light-emitting elements; the material of the N-type charge generation material layer consists of an electron transport compound and an N-type dopant; the electron transport compound contains a phenanthroline fragment or a phosphorus oxygen fragment.

According to an embodiment of the present disclosure, the display panel is provided with a partition structure between the light-emitting elements; and at least one layer of the common material layer is discontinuously provided at the partition structure.

According to an embodiment of the present disclosure, the display panel is provided with a pixel definition layer between the pixel electrode layer and the light-emitting function layer, and the partition structure is provided in the pixel definition layer.

According to an embodiment of the present disclosure, the light-emitting element includes a red light-emitting element, a green light-emitting element and a blue light-emitting element;
the partition structure is arranged between the red light-emitting element and the green light-emitting element.

According to an embodiment of the present disclosure, the light-emitting functional layer includes a hole injection material layer covering the gaps between the plurality of light-emitting elements; the hole injection material layer is discontinuously arranged at the partition structure.

According to an embodiment of the present disclosure, the light-emitting functional layer includes a charge-generation material layer covering gaps between the plurality of light-emitting elements, and the charge-generation material layer is discontinuously disposed at the partition structure.

According to an embodiment of the present disclosure, the display panel further includes an auxiliary electrode layer disposed on a side of the common electrode layer away from the driving backplane, and the auxiliary electrode layer is electrically connected to the common electrode layer and does not overlap with the light-emitting element.

According to an embodiment of the present disclosure, the display panel is provided with an organic cover layer between the common electrode layer and the auxiliary electrode layer; the organic cover layer includes a connection via hole exposing the common electrode layer, and the auxiliary electrode layer is electrically connected to the common electrode layer through the connection via hole.

According to another aspect of the present disclosure, a display apparatus is further provided, including the above-mentioned display panel.

It should be noted that the above general description and the following detailed description are merely exemplary and explanatory and should not be construed as limiting of the disclosure.

### BRIEF DESCRIPTION OF THE DRAWINGS

The drawings here are incorporated into the specification and constitute a part of the specification, show embodiments in consistent with the present disclosure, and are used together with the specification to explain principles of the present disclosure. Obviously, the drawings in the following description are only some embodiments of the present disclosure. For those of ordinary skill in the art, other drawings can be obtained based on these drawings without creative work.

FIG. 1 is a schematic structural diagram of a display panel in an embodiment of the present disclosure.

FIG. 2 is a partial structural schematic diagram of a pixel layer in an embodiment of the present disclosure.

FIG. 3 is a partial structural schematic diagram of a pixel layer in an embodiment of the present disclosure.

FIG. 4 is a partial structural schematic diagram of a display panel in an embodiment of the present disclosure.

FIG. 5 is a partial structural schematic diagram of a pixel layer in an embodiment of the present disclosure.

FIG. 6 is a schematic diagram of the structure of a light-emitting element in an embodiment of the present disclosure.

FIG. 7 is a schematic diagram of the structure of a light-emitting element in an embodiment of the present disclosure.

FIG. 8 is a schematic diagram of the structure of a light-emitting element in an embodiment of the present disclosure.

FIG. 9 is a schematic diagram of the structure of a light-emitting element in an embodiment of the present disclosure.

FIG. 10 is a partial structural schematic diagram of a pixel layer in an embodiment of the present disclosure.

FIG. 11 is a graph showing the relationship between the mass content of the P-type dopant in the hole injection material layer and the lateral current of the hole injection material layer in an embodiment of the present disclosure.

FIG. 12 is a schematic structural diagram of a pixel definition layer provided with a partition structure in an embodiment of the present disclosure.

FIG. 13 is a schematic structural diagram of a partition structure partitioning a common material layer in an embodiment of the present disclosure.

FIG. 14 is a schematic structural diagram of a pixel definition layer provided with a partition structure in an embodiment of the present disclosure.

FIG. 15 is a schematic structural diagram of a partition structure partitioning a common material layer in an embodiment of the present disclosure.

FIG. 16 is a schematic diagram of a structure in which an auxiliary electrode layer is provided on a pixel layer in an embodiment of the present disclosure.

### DESCRIPTION OF REFERENCE NUMERALS

AA, display area; AE, anode; BB, peripheral area; BEBL, electron blocking layer of blue light-emitting element; BEML, organic light-emitting layer of blue light-emitting element; B, blue light-emitting element; BP, substrate; Buff, inorganic buffer layer; CE, cathode; CFL, color filter layer; CGL, charge generation layer; CGLX, charge generation material layer; CML, organic cover layer; CNT, connection via; COML, common electrode layer; COMLX, auxiliary electrode layer; CVD1, first inorganic encapsulation layer; CVD2, second inorganic encapsulation layer; DBP, driving backplane; DH, row direction; DRL, driving layer; DV, column square; DX, first direction; DY, second direction; EBL, electron blocking layer; EFL, light-emitting functional layer; EFU, light-emitting functional unit; EIL, electron injection layer; EILX, electron injection material layer; ELS, light-emitting stack structure; EML, organic light-emitting layer; ETL, electron transport layer; ETLX, electron transport material layer; GEBL, electron blocking layer of green light-emitting element layer; GEML, organic light-emitting layer of green light-emitting element; GI, gate insulating layer; G, green light-emitting element; GT, gate layer; HBL, hole blocking layer; HBLX, hole blocking material layer; HIL, hole injection layer; HILX, hole injection material layer; HTL, hole transport layer; HTLX, hole transport material layer; IP, organic encapsulation layer; ILD, interlayer dielectric layer; NCGL, N-type charge generation layer; NCGLX, N-type charge generation material layer; PCGL, P-type charge generation layer; PCGLX, P-type charge generation material layer; PDL, pixel definition layer; PE, pixel electrode; PEL, pixel electrode layer; PIXL, pixel layer; PLN, planarization layer; PNL, display panel; PTS, partition structure; QDL, quantum dot layer; REBL, electron blocking layer of red light-emitting element; REML, organic light-emitting layer of red light-emitting element; R, red light-emitting element; SCL, semiconductor layer; SD, source and drain metal layer; TFE, thin film encapsulation layer; TFT, thin film transistor; TSL, touch function layer; LD, light-emitting element.

### DETAILED DESCRIPTION

Now, exemplary embodiments will be described more fully with reference to the accompanying drawings. However, the exemplary embodiments can be implemented in various forms and should not be construed as limited to the embodiments set forth herein. On the contrary, these embodiments are provided so that this disclosure will be thorough and complete, and will fully convey the concept of the exemplary embodiments to those skilled in the art. The same reference numerals in the drawings denote the same or similar structures, and thus their detailed descriptions will be omitted. In addition, the drawings are only schematic illustrations of the present disclosure and are not necessarily drawn to scale.

Although relative terms such as “upper” and “lower” are used in this specification to describe the relative relationship of one component to another component in the drawings, these terms are used in this specification for convenience only, for example, according to the direction of the example shown in the drawings. It can be understood that if the element in the drawing is turned upside down, the component described as “upper” will become “lower”. When a structure is “on” another structure, it may mean that the structure is integrally formed on the other structure, or that the structure is “directly” arranged on the other structure, or that the structure is “indirectly” arranged on the other structure through another structure.

The terms “a”, “an”, “the”, and “at least one” are used to indicate the presence of one or more elements/components/and the like; the terms “including” and “having” are used to indicate an open-ended inclusion and mean that in addition to the listed elements/components/and the like, there may be additional elements/components/and the like; the terms “first”, “second”, and “third” are used only as labels and are not intended to limit the number of their objects.

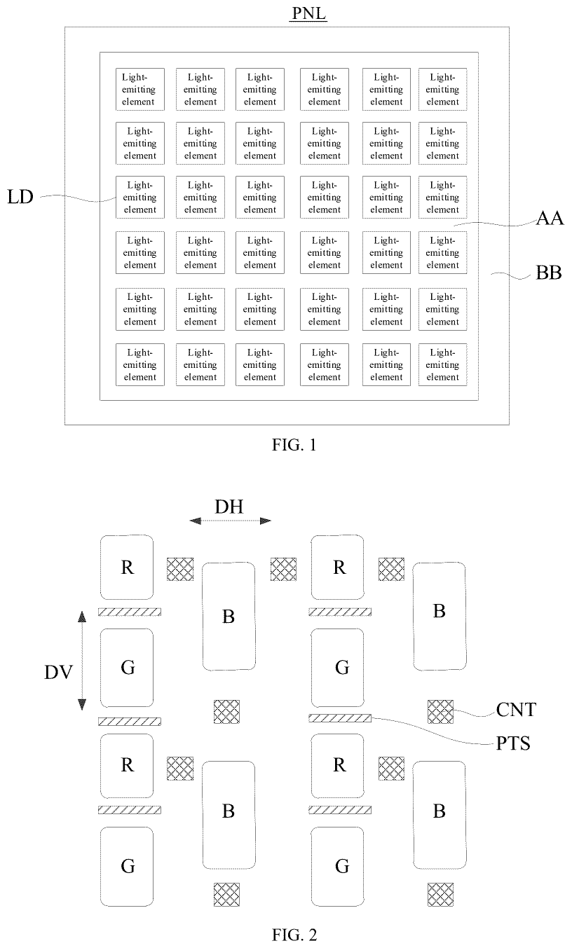

The embodiments of the present disclosure provide a display panel PNL, as shown in FIG. 1, which includes a display area AA and a peripheral area BB located on at least one side of the display area AA, for example, the peripheral area BB surrounds the display area AA. In the display area AA, the display panel PNL is provided with sub-pixels for display; in the peripheral area BB, the display panel PNL may not be provided with sub-pixels for display, or the sub-pixels provided are not used for displaying images.

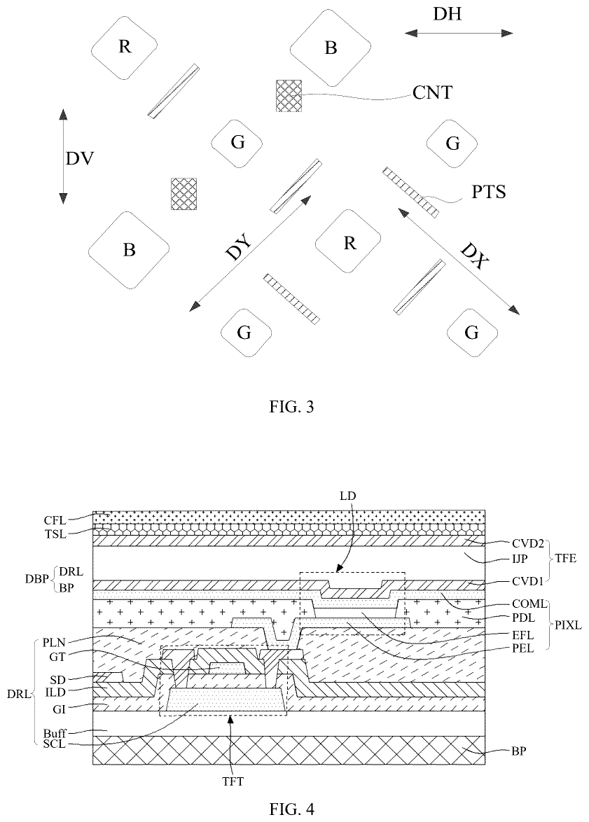

In the embodiments of the present disclosure, the sub-pixels in the display panel PNL are thin-film self-luminescence light-emitting elements LD, such as OLED, PLED, QLED, and the like. Furthermore, the light-emitting elements LD in the display area AA include light-emitting elements LD of different colors. For example, in the examples of FIG. 2 and FIG. 3, the light-emitting elements LD include red light-emitting elements R for emitting red light, blue light-emitting elements B for emitting blue light, and green light-emitting elements G for emitting green light. It can be understood that in other embodiments of the present disclosure, the light-emitting elements LD in the display area AA may also include only one color of light-emitting elements LD, or may include light-emitting elements LD of other colors (for example, yellow light-emitting elements for emitting yellow light, cyan light-emitting elements for emitting cyan light, white light-emitting elements for emitting white light, and the like).

In an embodiment of the present disclosure, as shown in FIG. 4, the display panel PNL may include a driving backplane DBP and a pixel layer PIXL stacked in sequence, wherein the pixel layer PIXL is provided with light-emitting elements LD, and the driving backplane DBP is used to drive the light-emitting elements LD in the pixel layer PIXL. The driving backplane DBP may adopt an active driving method to drive each light-emitting element LD, or may adopt a passive driving method to drive each light-emitting element LD.

In an embodiment of the present disclosure, as shown in FIG. 4, the driving backplane DBP includes a substrate BP and a driving layer DRL arranged on one side of the substrate BP; the pixel layer PIXL is arranged on the side of the driving layer DRL away from the substrate BP. The driving layer DRL is provided with a pixel driving circuit for driving the light-emitting elements LD; each light-emitting element LD can emit light under the driving of the pixel driving circuit to display images. Furthermore, the display panel PNL also includes a thin-film encapsulation layer TFE located on the side of the pixel layer PIXL away from the driving backplane DBP, and the thin-film encapsulation layer TFE can encapsulate and protect the pixel layer PIXL.

Optionally, the substrate BP may be an inorganic material substrate, an organic material substrate, or a composite substrate formed by stacking an inorganic material substrate and an organic material substrate. For example, in some embodiments of the present disclosure, the material of the substrate BP may be soda-lime glass, quartz glass, sapphire glass, and so on. In other embodiments of the present disclosure, the material of the substrate BP may be polymethyl methacrylate, polyvinyl alcohol, polyvinyl phenol, polyethersulfone, polyimide, polyamide, polyacetal, polycarbonate, polyethylene terephthalate, polyethylene naphthalate, or a combination thereof. In other embodiments of the present disclosure, the substrate BP may also be a flexible substrate, for example, the material of the substrate BP may include polyimide.

Optionally, in the driving layer DRL, any pixel driving circuit may include a thin-film transistor TFT and a storage capacitor. Furthermore, the thin-film transistor TFT may be selected from a top-gate thin-film transistor, a bottom-gate thin-film transistor, or a dual-gate thin-film transistor; the material of the active layer of the thin-film transistor may be amorphous silicon semiconductor material, low-temperature polysilicon semiconductor material, metal oxide semiconductor material, organic semiconductor material, carbon nanotube semiconductor material, or other types of semiconductor materials; the thin-film transistor may be an N-type thin-film transistor or a P-type thin-film transistor.

It can be understood that in the pixel driving circuit, any two transistors may be of the same type or different types. For example, in some embodiments, in a pixel driving circuit, some transistors may be N-type transistors and some transistors may be P-type transistors. For another example, in other embodiments, in a pixel driving circuit, some transistors may include active layers made of low-temperature polysilicon semiconductor material, and some transistors may include active layers made of metal oxide semiconductor material. In some embodiments of the present disclosure, the thin-film transistor is a low-temperature polysilicon transistor. In other embodiments of the present disclosure, some thin-film transistors are low-temperature polysilicon transistors, and some thin-film transistors are metal oxide transistors.

Optionally, the driving layer DRL may include a semiconductor layer SCL, a gate insulating layer GI, a gate layer GT, an interlayer dielectric layer ILD, a source-drain metal layer SD, a planarization layer PLN, and the like, stacked between the substrate BP and the pixel layer PIXL. Each thin-film transistor and storage capacitor may be formed by the semiconductor layer SCL, the gate insulating layer GI, the gate layer GT, the interlayer dielectric layer ILD, the source-drain metal layer SD, and the like. The positional relationship of each layer may be determined according to the layer structure of the thin-film transistor. Furthermore, the semiconductor layer SCL can be used to form the channel region of a transistor, and if necessary, partial routing or conductive structures can also be formed by conducting. The gate layer may be used to form one or more of the scan line, the reset control line, the light-emitting control line, and the like, and may also be used to form the gate of the transistor, and may also be used to form part or all of the electrode plate of the storage capacitor. The source-drain metal layer may be used to form the data line, the driving power supply voltage line, and the like, and may also be used to form part of the electrode plate of the storage capacitor. Of course, in other embodiments of the present disclosure, the driving layer DRL may also include other layers as needed, for example, it may also include a light-shielding layer between the semiconductor layer SCL and the substrate BP. As needed, any one of the above semiconductor layer SCL, gate layer GT, source-drain metal layer SD, and the like may also be multiple layers, for example, the driving layer DRL may include two different semiconductor layers SCL, or two or three source-drain metal layers SD, or two or three gate layers GT; accordingly, the insulating layers in the driving layer DRL (for example, the gate insulating layer GI, the interlayer dielectric layer ILD, the planarization layer PLN, and the like) may be increased or decreased as needed, or new insulating layers may be added as needed.

Optionally, the driving layer DRL may also include a passive layer, which may be arranged on the surface of the source-drain metal layer SD away from the substrate BP to protect the source-drain metal layer SD.

As an example, as shown in FIG. 4, the driving layer DRL may include an inorganic buffer layer Buff, a semiconductor layer SCL, a gate insulating layer GI, a gate layer GT, an interlayer dielectric layer ILD, a source-drain metal layer SD, and a planarization layer PLN stacked in sequence, so that the formed thin-film transistor is a top-gate thin-film transistor.

It can be understood that the above example of the driving backplane DBP is only one possible form of the driving backplane DBP in the embodiments of the present disclosure. In other embodiments of the present disclosure, the driving backplane DBP may also include other structures, for example, the driving backplane DBP may also be a passive driving glass substrate, a silicon-based driving substrate, and the like

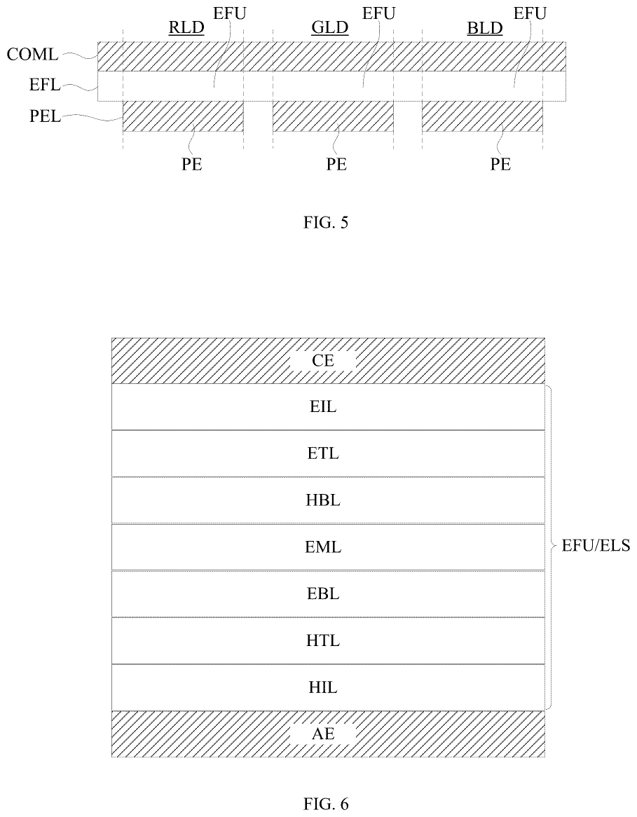

As shown in FIG. 4 and FIG. 5, the light-emitting elements LD in the pixel layer PIXL are thin-film light-emitting elements, which may include two electrodes stacked and a light-emitting functional unit EFU sandwiched between the two electrodes. For example, as shown in FIG. 4, the pixel layer PIXL may include a pixel electrode layer PEL, a light-emitting functional layer EFL, and a common electrode layer COML stacked in sequence. The pixel electrode layer PEL includes multiple pixel electrodes PE in the display area of the display panel; the part of the light-emitting functional layer EFL connected to the pixel electrode PE serves as the light-emitting functional unit EFU of the light-emitting element LD, and the common electrode layer COML serves as the common electrode and is electrically connected to the light-emitting functional unit EFU of each light-emitting element LD.

Furthermore, the pixel layer PIXL may also include a pixel definition layer PDL between the pixel electrode layer PEL and the light-emitting functional layer EFL. The pixel definition layer PDL includes multiple pixel openings corresponding to the multiple pixel electrodes PE, and any pixel opening exposes at least part of the area of the corresponding pixel electrode. For example, the pixel definition layer PDL covers the edges of the pixel electrode PE and exposes at least part of the internal area of the pixel electrode PE, so that the pixel definition layer PDL can effectively define the actual effective area of the pixel electrode PE (the area directly connected to the light-emitting functional unit EFU), thereby defining the light-emitting area and light-emitting area of the light-emitting element LD. The light-emitting functional layer EFL at least covers the pixel electrode PE exposed by the pixel definition layer PDL. The common electrode layer COML may cover the light-emitting functional layer EFL in the display area. The pixel electrode PE and the common electrode layer COML provide carriers such as electrons and holes to the light-emitting functional layer EFL, so that the light-emitting functional layer EFL emits light. The part of the light-emitting functional layer EFL between the pixel electrode PE and the common electrode layer COML may serve as the light-emitting functional unit EFU. The pixel electrode PE, the common electrode layer COML, and the light-emitting functional unit EFU form the light-emitting element LD. One of the pixel electrode PE and the common electrode layer COML serves as the anode of the light-emitting element LD, and the other serves as the cathode of the light-emitting element LD.

In an example, the pixel electrode PE serves as the anode of the light-emitting element LD, and the common electrode layer COML serves as the cathode of the light-emitting element LD.

It can be understood that the materials and layers of the light-emitting functional unit EFU are different for different types of light-emitting elements.

For example, as shown in FIG. 6, when the light-emitting element is an OLED, the light-emitting functional unit EFU may include an organic light-emitting layer EML, and may also include one or more of a hole injection layer HIL, a hole transport layer HTL, an electron blocking layer EBL, a hole blocking layer HBL, an electron transport layer ETL, and an electron injection layer EIL. Furthermore, the organic light-emitting layer EML may include a light-emitting layer host material and a light-emitting layer guest material, and the light-emitting layer guest material may be a fluorescent dopant or a phosphorescent dopant, especially a thermally activated delayed fluorescence material. As shown in FIG. 7, when the OLED adopts a stacked structure, a charge generation layer CGL may also be provided in the light-emitting functional layer EFL.

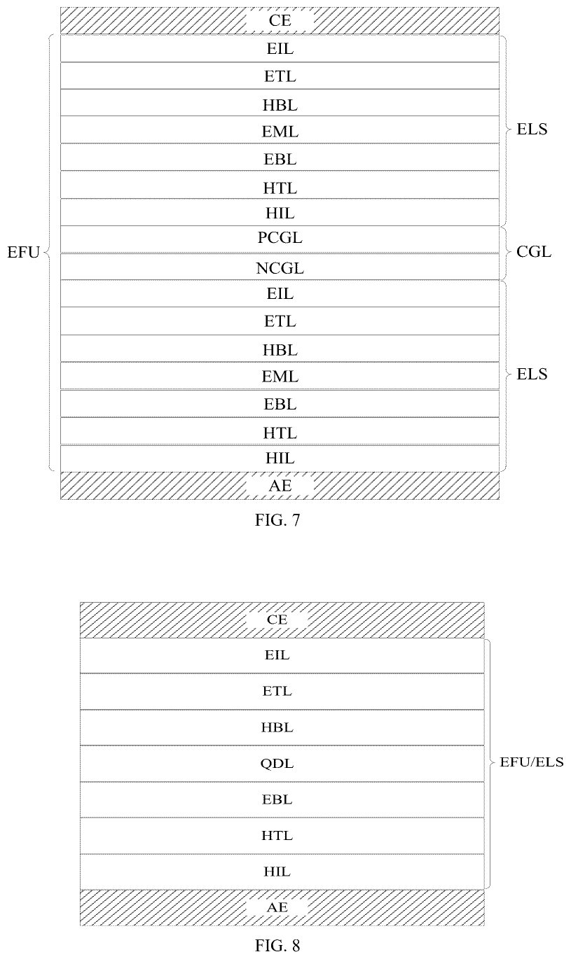

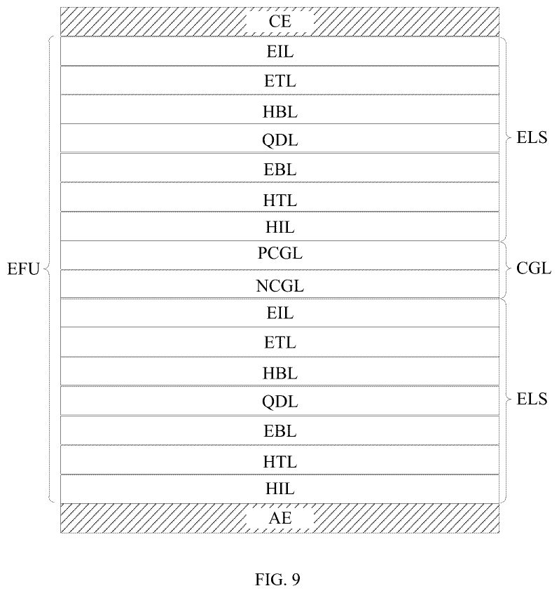

For another example, as shown in FIG. 8, when the light-emitting element is a QLED, the light-emitting functional unit EFU may include a quantum dot layer QDL, and may also include one or more of a hole injection layer HIL, an electron transport layer ETL, an electron blocking layer EBL, a hole blocking layer HBL, an electron transport layer ETL, and an electron injection layer EIL. Furthermore, the quantum dot layer QDL may include quantum dot particles, and the quantum dot particles may be connected to each other through surface modification groups. As shown in FIG. 9, when the QLED adopts a stacked structure, a charge generation layer CGL may also be provided in the light-emitting functional unit EFU.

In the embodiments of the present disclosure, as shown in FIG. 6 to FIG. 9, the light-emitting functional unit EFU may include one light-emitting stacked structure ELS, or may include multiple light-emitting stacked structures ELS stacked. When the light-emitting functional unit EFU includes multiple light-emitting stacked structures ELS, a charge generation layer CGL may be provided between adjacent light-emitting stacked structures ELS. Each light-emitting stacked structure ELS is provided with one or more light-emitting layers, and the light-emitting layer may be an organic light-emitting layer EML or a quantum dot layer QDL.

In the examples of FIG. 6 and FIG. 8, the light-emitting functional unit EFU includes one light-emitting stacked structure ELS. As shown in FIG. 6 and FIG. 8, the light-emitting element LD includes an anode AE, a light-emitting stacked structure ELS, and a cathode CE stacked in sequence; the light-emitting stacked structure ELS includes a hole adjustment layer, a light-emitting layer (for example, an organic light-emitting layer EML or a quantum dot layer QDL), and an electron adjustment layer stacked in sequence; the hole adjustment layer is located on the side of the light-emitting layer close to the anode AE, and the electron adjustment layer is located on the side of the light-emitting layer close to the cathode CE. The anode AE is used to inject holes into the light-emitting layer through the hole adjustment layer, and the cathode CE is used to inject electrons into the light-emitting layer through the electron adjustment layer. The hole adjustment layer and the electron adjustment layer are used to adjust the injection efficiency and injection speed of holes and electrons injected into the light-emitting layer, and to adjust the energy levels of the injected electrons and holes, improve the balance of hole injection and electron injection, and thereby improve the performance of the light-emitting functional unit EFU, for example, improve the light-emitting efficiency of the light-emitting element LD, improve the life of the light-emitting element LD, reduce the power supply voltage of the light-emitting element LD, and the like

The hole adjustment layer may include one or more of a hole injection layer HIL, a hole transport layer HTL, and an electron blocking layer EBL, wherein the hole injection layer HIL, the hole transport layer HTL, and the electron blocking layer EBL are stacked in sequence from the anode AE to the light-emitting layer. It can be understood that in some examples, one or more of the hole injection layer HIL, the hole transport layer HTL, and the electron blocking layer EBL may be provided as a multi-layer stacked structure, for example, the hole transport layer HTL may include a first hole transport layer and a second hole transport layer stacked.

The electron adjustment layer may include one or more of an electron injection layer EIL, an electron transport layer ETL, and a hole blocking layer HBL, wherein the electron injection layer EIL, the electron transport layer ETL, and the hole blocking layer HBL are stacked in sequence from the cathode CE to the light-emitting layer. It can be understood that in some examples, one or more of the electron injection layer EIL, the electron transport layer ETL, and the hole blocking layer HBL may be provided as a multi-layer stacked structure, for example, the electron transport layer ETL may include a first electron transport layer and a second electron transport layer stacked.

In the examples of FIG. 7 and FIG. 9, the light-emitting functional unit EFU includes multiple light-emitting stacked structures ELS stacked (two light-emitting stacked structures ELS are shown in FIG. 7 and FIG. 9). As shown in FIG. 7 and FIG. 9, the light-emitting element LD includes an anode AE, multiple light-emitting stacked structures ELS stacked, and a cathode CE. Any light-emitting stacked structure ELS includes a hole adjustment layer, a light-emitting layer (for example, an organic light-emitting layer EML or a quantum dot layer QDL), and an electron adjustment layer stacked in sequence, the hole adjustment layer is located on the side of the light-emitting layer close to the anode AE, and the electron adjustment layer is located on the side of the light-emitting layer close to the cathode CE.

Optionally, the light-emitting functional unit EFU may also include a charge generation layer CGL between adjacent light-emitting stacked structures ELS to improve the efficiency of injecting electrons and holes into the adjacent light-emitting stacked structures ELS. For example, the charge generation layer CGL includes an N-type charge generation layer NCGL and a P-type charge generation layer PCGL stacked between adjacent light-emitting stacked structures ELS; the N-type charge generation layer NCGL is adjacent to the electron adjustment layer of one light-emitting stacked structure ELS and is used to inject electrons into the electron adjustment layer of the light-emitting stacked structure ELS; the P-type charge generation layer PCGL is adjacent to the hole adjustment layer of the other light-emitting stacked structure ELS and is used to inject holes into the hole adjustment layer of the light-emitting stacked structure ELS. In other words, the P-type charge generation layer PCGL is arranged on the side of the N-type charge generation layer NCGL away from the anode AE. Of course, it can be understood that in other examples, the charge generation layer CGL may also include other structures.

It can be understood that in some other embodiments of the present disclosure, the electron adjustment layer of the light-emitting stacked structure ELS may be omitted, or may include other structures in addition to the electron injection layer EIL, the electron transport layer ETL, and the hole blocking layer HBL.

It can be understood that in some other embodiments of the present disclosure, the hole adjustment layer of the light-emitting stacked structure ELS may be omitted, or may include other structures in addition to the hole injection layer HIL, the hole transport layer HTL, and the electron blocking layer EBL.

It can be understood that when multiple light-emitting layers are provided in the light-emitting stacked structure ELS, the colors of the multiple light-emitting layers may be the same or different, and the types of the multiple light-emitting layers may be the same or different. For example, two light-emitting layers are provided in a light-emitting stacked structure ELS, and the two light-emitting layers may be a red organic light-emitting layer EML and a green organic light-emitting layer EML stacked. For another example, two light-emitting layers are provided in a light-emitting stacked structure ELS, and the two light-emitting layers may be a red organic light-emitting layer EML and a red quantum dot layer QDL stacked.

It can be understood that for any light-emitting stack structure (ELS), it can be provided with a light-emitting layer (such as a quantum dot layer QDL or an organic light-emitting layer EML), as well as one or more of a hole injection layer HIL, an electron transport layer ETL, an electron blocking layer EBL, a hole blocking layer HBL, an electron transport layer ETL, and an electron injection layer EIL, or other layers can be added as needed. Of course, in the light-emitting stack structure ELS, one or more of the hole injection layer HIL, the electron transport layer ETL, the electron blocking layer EBL, the hole blocking layer HBL, the electron transport layer ETL, and the electron injection layer EIL can also be omitted. For the two light-emitting stack structures ELS of the same light-emitting element LD, the layer structures of the two light-emitting stack structures ELS can be the same or different.

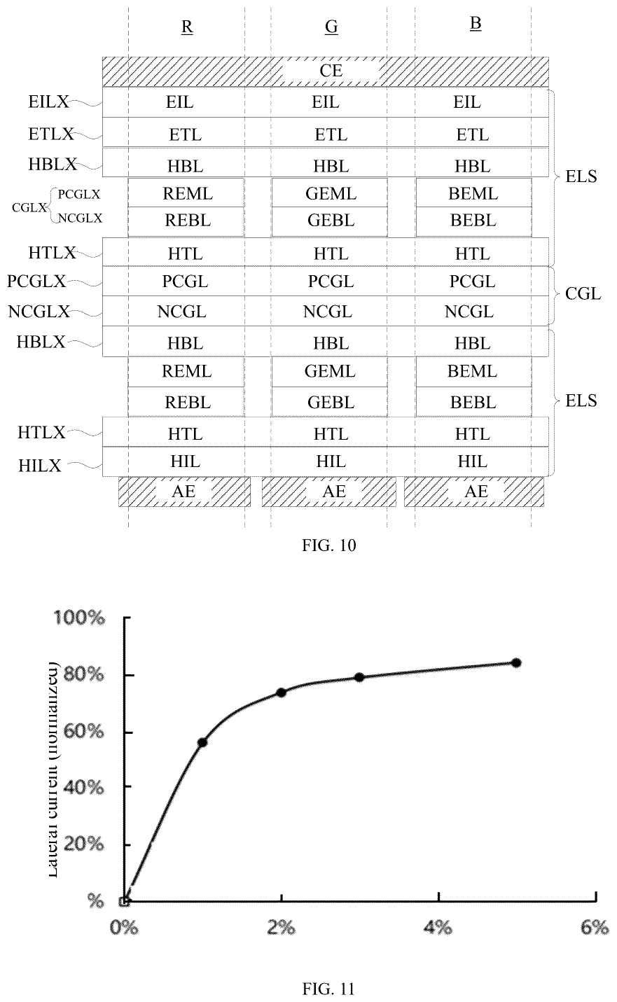

For example, in the example shown in FIG. 10, the display panel PNL is provided with three different colors of light-emitting elements LD: red light-emitting element R, green light-emitting element G, and blue light-emitting element B; the light-emitting functional unit EFU of each light-emitting element LD includes a light-emitting stack structure ELS, a charge generation layer CGL, and a light-emitting stack structure ELS stacked in sequence. In this example, the light-emitting stack structure ELS close to the anode AE includes a hole injection layer HIL, a hole transport layer HTL, an electron blocking layer EBL (such as an electron blocking layer REBL of a red light-emitting element, an electron blocking layer GEBL of a green light-emitting element, or an electron blocking layer BEBL of a blue light-emitting element), an organic light-emitting layer EML (such as the organic light-emitting layer REML of the red light-emitting element, the organic light-emitting layer GEML of the green light-emitting element, or the organic light-emitting layer BEML of the blue light-emitting element), and a hole blocking layer HBL stacked in sequence; in other words, the electron transport layer and the electron injection layer are omitted in this light-emitting stack structure ELS. In this example, the light-emitting stack structure ELS close to the cathode CE includes a hole transport layer HTL, an electron blocking layer EBL (such as the electron blocking layer REBL of the red light-emitting element, the electron blocking layer GEBL of the green light-emitting element, or the electron blocking layer BEBL of the blue light-emitting element), an organic light-emitting layer EML (such as the organic light-emitting layer REML of the red light-emitting element, the organic light-emitting layer GEML of the green light-emitting element, or the organic light-emitting layer BEML of the blue light-emitting element), a hole blocking layer HBL, an electron transport layer ETL, and a hole injection layer HIL stacked in sequence; in other words, the hole injection layer is omitted in this light-emitting stack structure ELS.

Referring to FIG. 4, the thin film encapsulation layer TFE can be located on the surface of the pixel layer PIXL away from the substrate BP, which can include alternately stacked inorganic encapsulation layers and organic encapsulation layers. The inorganic encapsulation layer can effectively block external moisture and oxygen, preventing the invasion of water and oxygen into the pixel layer PIXL and causing the materials in the pixel layer PIXL to age. Optionally, the edges of the inorganic encapsulation layer can be located in the peripheral area. The organic encapsulation layer is located between adjacent inorganic encapsulation layers to achieve planarization and reduce the stress between the inorganic encapsulation layers. The edges of the organic encapsulation layer can be located between the edge of the display area and the edge of the inorganic encapsulation layer. For example, the thin film encapsulation layer TFE includes a first inorganic encapsulation layer CVD1, an organic encapsulation layer IJP, and a second inorganic encapsulation layer CVD2 stacked in sequence on the side of the pixel layer PIXL away from the substrate BP. Of course, in other embodiments of the present disclosure, the display panel may not be provided with a thin film encapsulation layer, but other methods can be used to encapsulate and protect the pixel layer.

In some embodiments of the present disclosure, referring to FIG. 4, the display panel PNL can also include a touch function layer TSL, which can be located on the side of the thin film encapsulation layer TFE away from the driving backplane DBP, so that the display panel PNL includes touch functionality.

In some embodiments of the present disclosure, referring to FIG. 4, the display panel PNL can also include a color filter layer CFL, which can be located on the side of the thin film encapsulation layer TFE away from the driving backplane DBP, to reduce the reflection of ambient light and improve display quality.

In the embodiments of the present disclosure, due to process reasons, such as when using an open mask process, the light-emitting functional layer EFL may include a common material layer, which can cover the gaps between a plurality of light-emitting elements LD, causing adjacent light-emitting elements LD to be connected through the common material layer. For example, the common material layer can cover the display area AA and be applied to each light-emitting functional unit EFU at the same time, and the part of the common material layer in each light-emitting functional unit EFU serves as the structural layer of the light-emitting functional unit EFU (such as one of the hole injection layer HIL, the hole transport layer HTL, the electron blocking layer EBL, the N-type charge generation layer NCGL, the P-type charge generation layer PCGL, the hole blocking layer HBL, the electron transport layer ETL, and the electron injection layer EIL).

For example, in the example shown in FIG. 10, the light-emitting functional layer EFL is provided with a hole injection material layer HILX, a hole transport material layer HTLX, a hole blocking material layer HBLX, an N-type charge generation material layer NCGLX, a P-type charge generation material layer PCGLX, an electron transport material layer ETLX, and an electron injection material layer EILX. The hole injection material layer HILX covers the gaps between a plurality of light-emitting elements, such as covering the display area AA; the part of the hole injection material layer HILX located in each light-emitting functional unit EFU serves as the hole injection layer HIL of the light-emitting functional unit EFU; the hole injection material layer HILX is a common material layer of the light-emitting functional layer EFL. The hole transport material layer HTLX covers the gaps between a plurality of light-emitting elements, such as covering the display area AA; the part of the hole transport material layer HTLX located in each light-emitting functional unit EFU serves as the hole transport layer HTL of the light-emitting functional unit EFU; the hole transport material layer HTLX is a common material layer of the light-emitting functional layer EFL. The hole blocking material layer HBLX covers the gaps between a plurality of light-emitting elements, such as covering the display area AA; the part of the hole blocking material layer HBLX located in each light-emitting functional unit EFU serves as the hole blocking layer HBL of the light-emitting functional unit EFU; the hole blocking material layer HBLX is a common material layer of the light-emitting functional layer EFL. The N-type charge generation material layer NCGLX covers the gaps between a plurality of light-emitting elements, such as covering the display area AA; the part of the N-type charge generation material layer NCGLX located in each light-emitting functional unit EFU serves as the N-type charge generation layer NCGL of the light-emitting functional unit EFU; the N-type charge generation material layer NCGLX is a common material layer of the light-emitting functional layer EFL. The P-type charge generation material layer PCGLX covers the gaps between a plurality of light-emitting elements, such as covering the display area AA; the part of the P-type charge generation material layer PCGLX located in each light-emitting functional unit EFU serves as the P-type charge generation layer PCGL of the light-emitting functional unit EFU; the P-type charge generation material layer PCGLX is a common material layer of the light-emitting functional layer EFL. The electron transport material layer ETLX covers the gaps between a plurality of light-emitting elements, such as covering the display area AA; the part of the electron transport material layer ETLX located in each light-emitting functional unit EFU serves as the electron transport layer ETL of the light-emitting functional unit EFU; the electron transport material layer ETLX is a common material layer of the light-emitting functional layer EFL. The electron injection material layer EILX covers the gaps between a plurality of light-emitting elements, such as covering the display area AA; the part of the electron injection material layer EILX located in each light-emitting functional unit EFU serves as the electron injection layer EIL of the light-emitting functional unit EFU; the electron injection material layer EILX is a common material layer of the light-emitting functional layer EFL.

It can be understood that the common material layer illustrated in FIG. 10 is only an example of the common material layer in the embodiments of the present disclosure. In other embodiments of the present disclosure, other common material layers can be provided, or at least part of the common material layers illustrated in FIG. 10 can be omitted.

However, when a light-emitting element LD is loaded with a driving current to emit light, the driving current may leak laterally along the common material layer to another light-emitting element LD, causing the other light-emitting element LD to emit light, which results in crosstalk between adjacent light-emitting elements LD. Especially, when the green light-emitting element G emits light, it can cause the adjacent red light-emitting element R to emit light. The lower the gray level of the green light-emitting element G, the closer the gray level of the crosstalked red light-emitting element R is to the gray level of the green light-emitting element G, which makes the crosstalk more severe.

When the inventor analyzed this crosstalk, it was found that in related technologies, the lateral resistance of some common material layers in the light-emitting functional layer EFL is relatively small, which leads to severe lateral leakage. Especially, the lateral resistance of at least part of the common material layers with hole transport materials in the light-emitting functional layer EFL is relatively small, resulting in a large lateral current. For example, in some related technologies, the hole injection layer and the hole transport layer use the same hole transport materials, and the lateral resistance of these hole transport materials is relatively small; moreover, the hole injection layer is doped with P-type dopants, which increases the lateral current of the hole injection layer by hundreds of times.

Therefore, in some embodiments of the present disclosure, at least one common material layer of the light-emitting functional layer EFL can include a hole-transport-type nitrogen-containing compound, and the structural formula of the hole-transport-type nitrogen-containing compound is as shown in Chemical Formula 1:

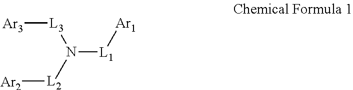

wherein, L₁, L₂, L₃ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
Ar₁ to Ar₃ are each independently selected from a substituted or unsubstituted aryl with 6 to 50 ring carbon atoms, a substituted or unsubstituted heteroaryl with 5 to 40 ring carbon atoms, and —N(Ar₄Ar₅); Ar₄ and Ar₅ are each independently selected from a substituted or unsubstituted aryl with 6 to 50 ring carbon atoms, a substituted or unsubstituted heteroaryl with 5 to 40 ring carbon atoms; wherein at least one of Ar₁ to Ar₃ contains a benzopentacyclic fragment or a dithiophene fragment;
when L₁, L₂, L₃, Ar₁, Ar₂, Ar₃, Ar₄ or Ar₅ has a substituent, the substituent is selected from deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms.

In this embodiment, at least one common material layer uses a hole-transport-type nitrogen-containing compound, for example, the hole injection material layer HILX or the hole transport material layer HTLX uses a hole-transport-type nitrogen-containing compound. The hole-transport-type nitrogen-containing compound contains a benzopentacyclic fragment or a dithiophene fragment, which makes the hole-transport-type nitrogen-containing compound have a large steric hindrance and a large lateral resistance, thereby reducing the lateral leakage of the common material layer using the hole-transport-type nitrogen-containing compound, and weakening or eliminating the crosstalk between adjacent light-emitting elements LD.

In an embodiment of the present disclosure, the L₁, L₂ and L₃ are each independently selected from a single bond, a substituted or unsubstituted phenylene, a substituted or unsubstituted biphenylene, a substituted or unsubstituted terphenylene, a substituted or unsubstituted naphthylene, and a substituted or unsubstituted trimethyleneene.

In an embodiment of the present disclosure, when L₁, L₂ and L₃ have substituents, the substituents are selected from deuterium, fluorine, methyl, ethyl, propyl, isopropyl, tert-butyl, cyclofluorenyl, cyclohexyl, adamantyl, phenyl, naphthyl, biphenyl, carbazolyl, benzothiophenyl and benzofuranyl.

In an example, L₁, L₂ and L₃ are each independently selected from a single bond, a phenylene, a biphenylene, a terphenylene, a naphthylene, and a trimphenylene.

In an embodiment of the present disclosure, when Ar₁, Ar₂, Ar₃, Ar₄ or Ar₅ has a substituent, the substituent is selected from deuterium, fluorine, methyl, ethyl, propyl, isopropyl, tert-butyl, cyclofluorenyl, cyclohexyl, adamantyl, phenyl, naphthyl, biphenyl, carbazolyl, benzothiophenyl, and benzofuranyl.

In an embodiment of the present disclosure, at least one of Ar₁ to Ar₃ has a group shown in the following Chemical Formula 2 or Chemical Formula 3:

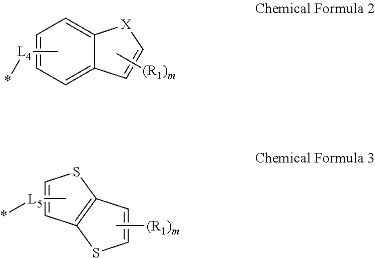

wherein, * indicates connection with L₁, L₂, L₃ or N;
L₄, L₅ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
X is selected from N(R₂), C(R₃R₄), O, S, Si (R₃R₄); m is 0, 1 or 2;
R₁ is selected from the group consisting of deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms;
R₂ to R₄ are each independently selected from a substituted or unsubstituted alkyl with 1 to 10 carbon atoms, a substituted or unsubstituted cycloalkyl with 5 to 10 carbon atoms, a substituted or unsubstituted aryl with 6 to 30 carbon atoms, or a substituted or unsubstituted heteroaryl with 5 to 30 carbon atoms;
When the number of R₁ is two and they are connected to two adjacent carbon atoms respectively, the two R₁ can also be connected to each other to form an aromatic ring or an aliphatic ring;
R₃ and R₄ can also be connected to each other to form an aromatic ring or an aliphatic ring. It is understood that R₃ and R₄ can be independently connected to C or Si without being connected to each other to form a ring, or they can be connected to each other to form an aromatic ring or an aliphatic ring.

In an example, when L₄ and L₅ have a substituent, the substituent is selected from deuterium, fluorine, methyl, ethyl, propyl, isopropyl, tert-butyl, cyclofluorenyl, cyclohexyl, adamantyl, phenyl, naphthyl, biphenyl, carbazolyl, benzothiophenyl, and benzofuranyl.

In an example, L₄ and L₅ are each independently selected from a single bond, a phenylene, a biphenylene, a terphenylene, a naphthyl, and a trimphenylene.

In an example, R₁ is selected from deuterium, fluorine, methyl, ethyl, propyl, isopropyl, tert-butyl, cyclofluorenyl, cyclohexyl, adamantyl, phenyl, naphthyl, biphenyl, carbazolyl, benzothienyl, and benzofuranyl.

In an example, R₂ to R₄ are each independently selected from methyl, ethyl, propyl, isopropyl, tert-butyl, cyclofluorenyl, cyclohexyl, adamantyl, phenyl, naphthyl, biphenyl, carbazolyl, benzothiophenyl, and benzofuranyl.

In an embodiment of the present disclosure, the Ar₁ to Ar₅ are each independently selected from 9,9′-dimethylfluorenyl, spirofluorenyl, benzothiophenyl, N-phenylcarbazolyl, phenyl, biphenyl, 9-phenyl-1,2,3,4-tetrahydrocarbazolyl, phenyl-substituted thieno[3,2-b]thienyl, thieno[3,2-b]thienyl, naphthyl, 9,9′-diphenylfluorenyl, dibenzofuranyl, dibenzothienyl; and at least one of Ar₁ to Ar₃ contains phenyl-substituted thieno[3,2-b]thienyl or thieno[3,2-b]thienyl.

In an embodiment of the present disclosure, the hole-transport-type nitrogen-containing compound is selected from the group consisting of the following compounds:

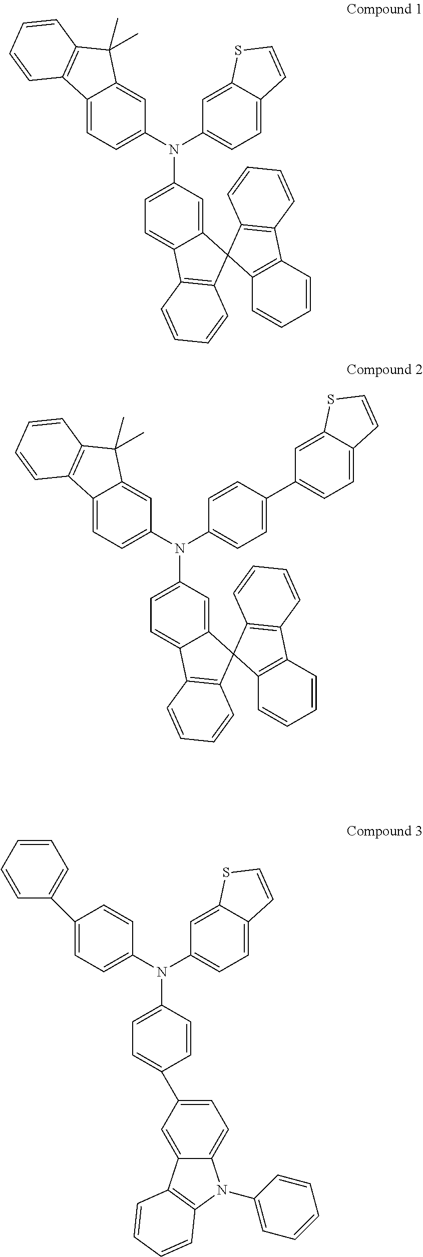 [SMILES: CC1(C)c2ccccc2-c2ccc(N(c3ccc4c(c3)C3(c5ccccc5-c5ccccc53)c3ccccc3-4)c3ccc4ccsc4c3)cc21 ; CC1(C)c2ccccc2-c2ccc(N(c3ccc(-c4ccc5ccsc5c4)cc3)c3ccc4c(c3)C3(c5ccccc5-c5ccccc53)c3ccccc3-4)cc21 ; c1ccc(-c2ccc(N(c3ccc(-c4ccc5c(c4)c4ccccc4n5-c4ccccc4)cc3)c3ccc4ccsc4c3)cc2)cc1]

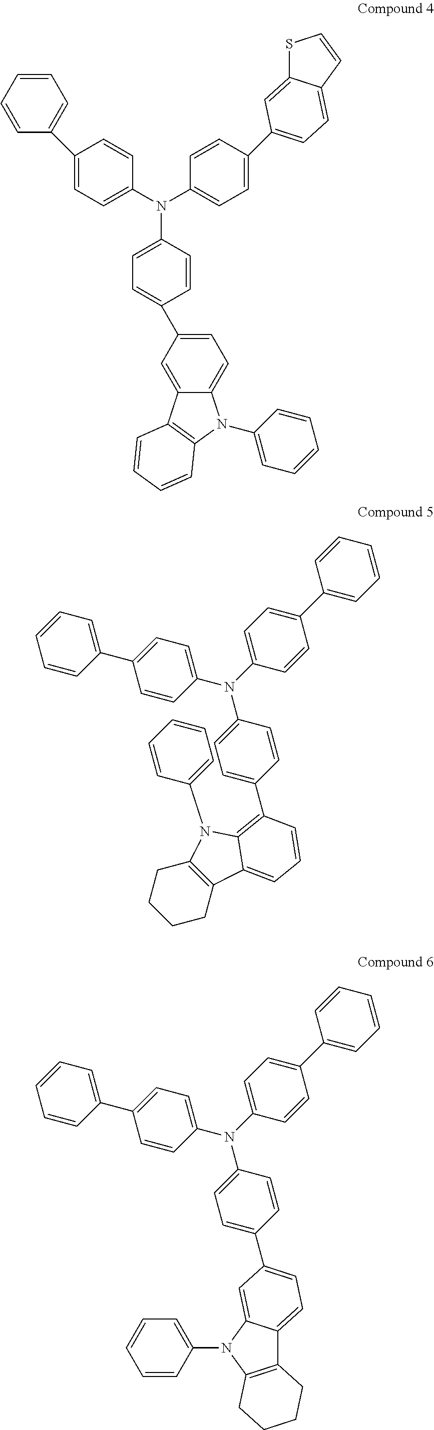 [SMILES: c1ccc(-c2ccc(N(c3ccc(-c4ccc5ccsc5c4)cc3)c3ccc(-c4ccc5c(c4)c4ccccc4n5-c4ccccc4)cc3)cc2)cc1 ; c1ccc(-c2ccc(N(c3ccc(-c4ccccc4)cc3)c3ccc(-c4cccc5c6c(n(-c7ccccc7)c45)CCCC6)cc3)cc2)cc1 ; c1ccc(-c2ccc(N(c3ccc(-c4ccccc4)cc3)c3ccc(-c4ccc5c6c(n(-c7ccccc7)c5c4)CCCC6)cc3)cc2)cc1]

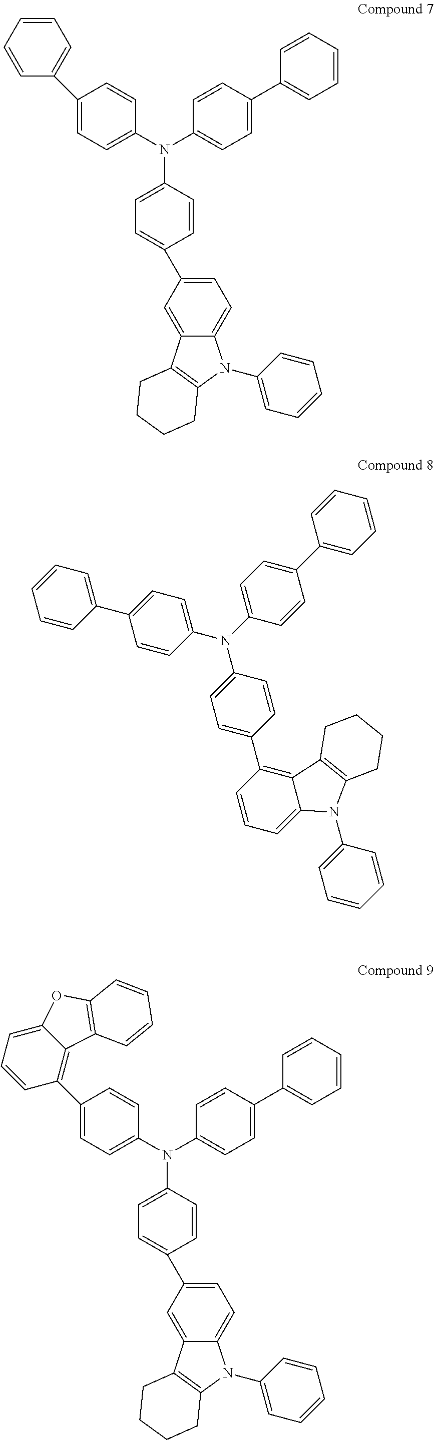 [SMILES: c1ccc(-c2ccc(N(c3ccc(-c4ccccc4)cc3)c3ccc(-c4ccc5c(c4)c4c(n5-c5ccccc5)CCCC4)cc3)cc2)cc1 ; c1ccc(-c2ccc(N(c3ccc(-c4ccccc4)cc3)c3ccc(-c4cccc5c4c4c(n5-c5ccccc5)CCCC4)cc3)cc2)cc1 ; c1ccc(-c2ccc(N(c3ccc(-c4ccc5c(c4)c4c(n5-c5ccccc5)CCCC4)cc3)c3ccc(-c4cccc5oc6ccccc6c45)cc3)cc2)cc1]

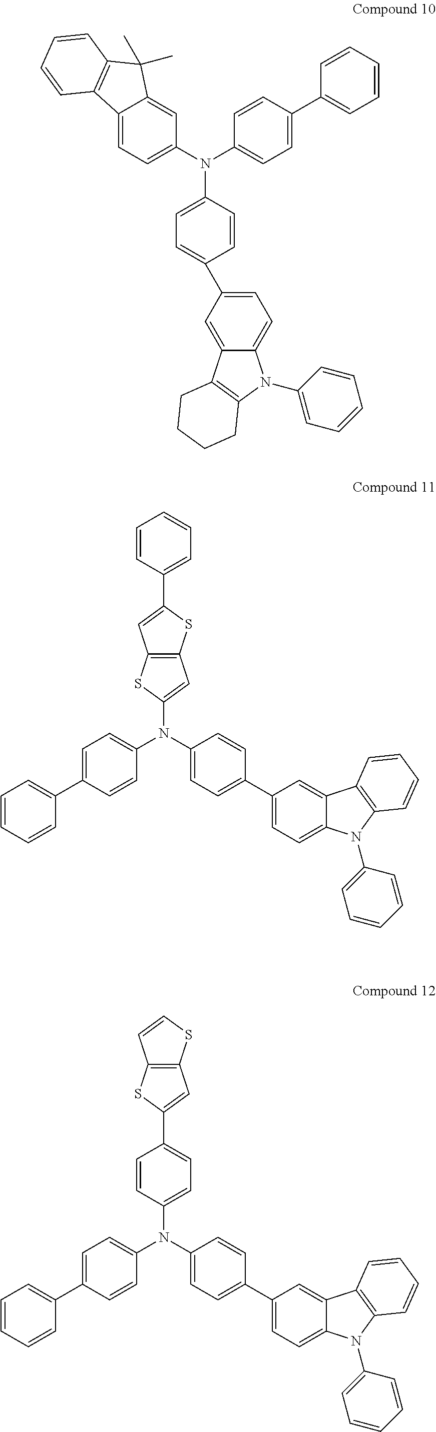 [SMILES: CC1(C)c2ccccc2-c2ccc(N(c3ccc(-c4ccccc4)cc3)c3ccc(-c4ccc5c(c4)c4c(n5-c5ccccc5)CCCC4)cc3)cc21 ; c1ccc(-c2ccc(N(c3ccc(-c4ccc5c(c4)c4ccccc4n5-c4ccccc4)cc3)c3cc4sc(-c5ccccc5)cc4s3)cc2)cc1 ; c1ccc(-c2ccc(N(c3ccc(-c4ccc5c(c4)c4ccccc4n5-c4ccccc4)cc3)c3ccc(-c4cc5sccc5s4)cc3)cc2)cc1]

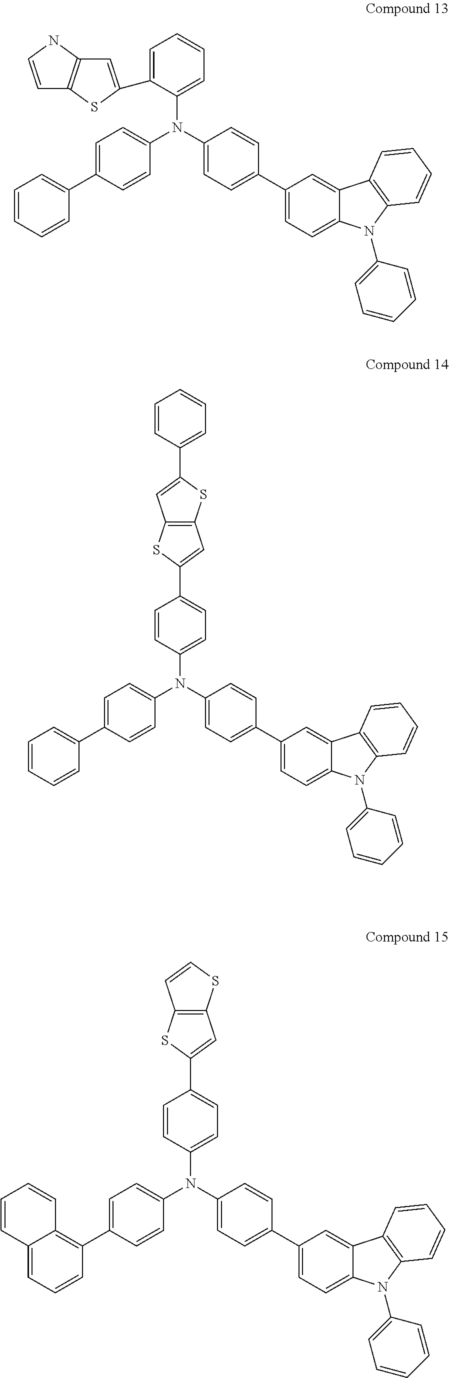 [SMILES: c1ccc(-c2ccc(N(c3ccc(-c4ccc5c(c4)c4ccccc4n5-c4ccccc4)cc3)c3ccccc3-c3cc4[nH]ccc4s3)cc2)cc1 ; c1ccc(-c2ccc(N(c3ccc(-c4ccc5c(c4)c4ccccc4n5-c4ccccc4)cc3)c3ccc(-c4cc5sc(-c6ccccc6)cc5s4)cc3)cc2)cc1 ; c1ccc(-n2c3ccccc3c3cc(-c4ccc(N(c5ccc(-c6cc7sccc7s6)cc5)c5ccc(-c6cccc7ccccc67)cc5)cc4)ccc32)cc1]

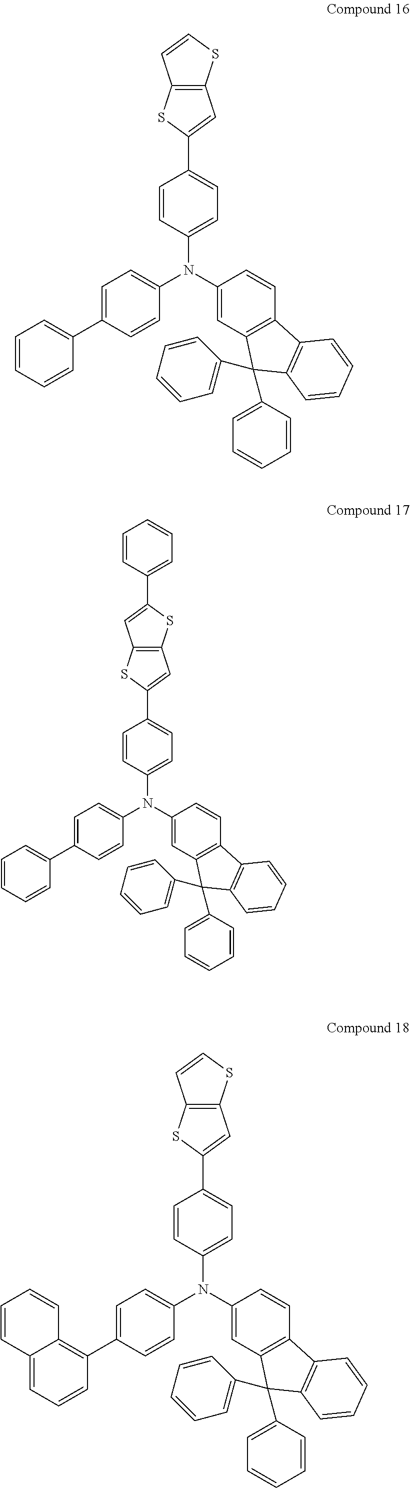 [SMILES: c1ccc(-c2ccc(N(c3ccc(-c4cc5sccc5s4)cc3)c3ccc4c(c3)C(c3ccccc3)(c3ccccc3)c3ccccc3-4)cc2)cc1 ; c1ccc(-c2ccc(N(c3ccc(-c4cc5sc(-c6ccccc6)cc5s4)cc3)c3ccc4c(c3)C(c3ccccc3)(c3ccccc3)c3ccccc3-4)cc2)cc1 ; c1ccc(C2(c3ccccc3)c3ccccc3-c3ccc(N(c4ccc(-c5cc6sccc6s5)cc4)c4ccc(-c5cccc6ccccc56)cc4)cc32)cc1]

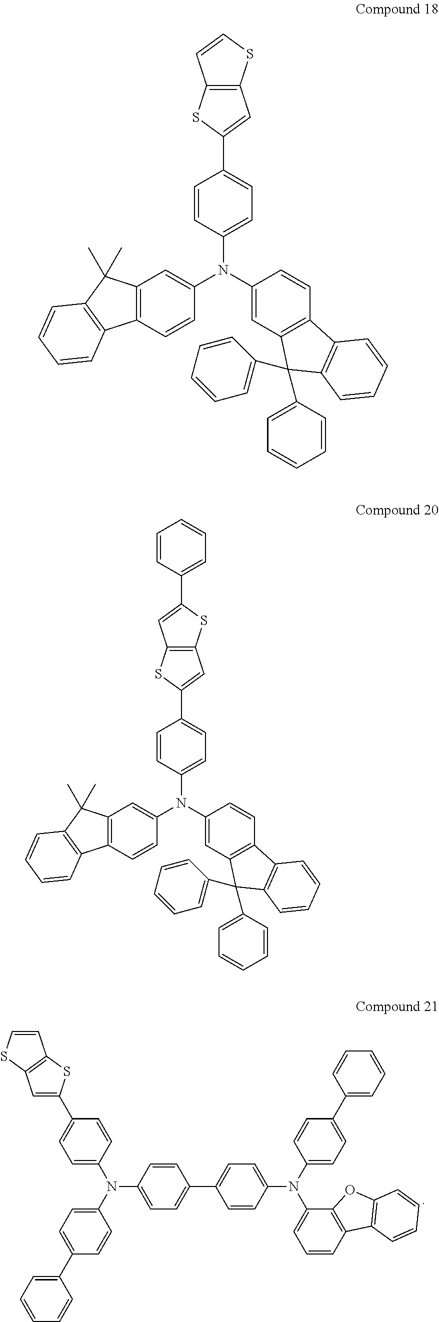 [SMILES: CC1(C)c2ccccc2-c2ccc(N(c3ccc(-c4cc5sccc5s4)cc3)c3ccc4c(c3)C(c3ccccc3)(c3ccccc3)c3ccccc3-4)cc21 ; CC1(C)c2ccccc2-c2ccc(N(c3ccc(-c4cc5sc(-c6ccccc6)cc5s4)cc3)c3ccc4c(c3)C(c3ccccc3)(c3ccccc3)c3ccccc3-4)cc21 ; c1ccc(-c2ccc(N(c3ccc(-c4ccc(N(c5ccc(-c6ccccc6)cc5)c5cccc6c5oc5ccccc56)cc4)cc3)c3ccc(-c4cc5sccc5s4)cc3)cc2)cc1]

In the embodiment of the present disclosure, the performance of some hole-transport-type nitrogen-containing compounds was also tested. In this test, the control compound used was the common hole transport compound NPB. Both the test compound and the control compound were doped with 3% of P-type dopant, and then the lateral current was measured at a test voltage of 10V. The test results were normalized to the lateral current of NPB as the benchmark. The test results are shown in Table 1:

TABLE 1

| Compound | Lateral current |
|---|---|
| NPB (Reference compound) | 100.0% |
| Compound 1 | 11.9% |
| Compound 2 | 50.2% |
| Compound 3 | 52.6% |
| Compound 4 | 48.1% |
| Compound 5 | 60.2% |
| Compound 6 | 46.3% |
| Compound 7 | 70.1% |
| Compound 8 | 50% |
| Compound 9 | 49.2% |
| Compound 10 | 61.2% |
| Compound 16 | 10.1% |
| Compound 17 | 8.7% |
| Compound 18 | 8.90% |
| Compound 19 | 7.80% |
| Compound 20 | 11.3% |
| Compound 21 | 35.4% |

It can be seen from the test data in Table 1 that the hole-transport-type nitrogen-containing compound provided in the embodiment of the present disclosure can effectively reduce the lateral current. Therefore, when the hole-transport-type nitrogen-containing compound is applied to the common material layer of the light-emitting functional layer EFL, it can avoid that the lateral current of the common material layer is too large to cause crosstalk between different light-emitting elements LD.

In some embodiments of the present disclosure, L₁, L₂ and L₃ are all single bonds, so that the hole-transport-type nitrogen-containing compound has a large steric hindrance, thereby reducing the lateral current of the hole-transport-type nitrogen-containing compound after film formation.

In some embodiments of the present disclosure, at least one of Ar₁, Ar₂, and Ar₃ is a 9,9′-dimethylfluorenyl, 9,9′-diphenylfluorenyl, or spirofluorenyl, and the fluorenyl group is connected to the central nitrogen atom of the hole-transporting nitrogen-containing compound by a single bond; at least one of Ar₁, Ar₂, and Ar₃ is a substituted or unsubstituted thieno[3,2-b]thienyl, or a substituted or unsubstituted benzothienyl; wherein, either the substituted or unsubstituted benzothienyl is connected to the central nitrogen atom of the hole-transporting nitrogen-containing compound by a single bond, and the substituted or unsubstituted thieno[3,2-b]thienyl can be connected to the central nitrogen atom of the hole-transporting nitrogen-containing compound by a single bond or a phenylene group.

It is understood that in the light-emitting functional layer EFL of the embodiment of the present disclosure, there may be multiple common material layers with hole transport materials. The hole-transport-type nitrogen-containing compound provided in the embodiment of the present disclosure may be present in only one layer of these common material layers, or may be present in multiple layers; the embodiment of the present disclosure does not necessarily require that all hole transport materials in the light-emitting functional layer EFL are hole-transport-type nitrogen-containing compounds.

In an embodiment of the present disclosure, the light-emitting functional layer EFL includes a hole injection material layer HILX, and the hole injection material layer HILX covers the gaps between the plurality of light-emitting elements, for example, covers the display area AA. In this way, the hole injection material layer HILX is a common material layer of the light-emitting functional layer EFL. The portion of the hole injection material layer HILX in each light-emitting functional unit EFU can serve as the hole injection layer HIL of the light-emitting functional unit EFU. In this embodiment, the hole injection material layer HILX can include the above-mentioned hole-transport-type nitrogen-containing compound, thereby reducing the lateral resistance of the hole injection material layer HILX.

In some examples of this embodiment, the hole injection material layer HILX may also contain a P-type dopant to enhance the hole injection capability of the hole injection layer HIL. The mass content of the P-type dopant in the hole injection material layer HILX does not exceed 3% to avoid excessive lateral current of the hole injection material layer HILX due to excessive content of the P-type dopant. Furthermore, the mass content of the P-type dopant in the hole injection material layer HILX is 0.5% to 1.5%, for example, 1%.

In some examples of this embodiment, the material of the hole injection material layer HILX may consist of a hole-transport-type nitrogen-containing compound and a P-type dopant; the mass content of the P-type dopant is between 0.5% and 1.5%. Compared with the related art, the lateral current of the hole injection material layer HILX can be greatly reduced, so that the crosstalk between the light-emitting elements LD is greatly reduced or eliminated.

This embodiment also provides test results of the lateral current of the hole injection material layer HILX when the hole injection material layer HILX includes different doping amounts (mass content) of the P-type dopant. Referring to FIG. 11, when the mass content of the P-type dopant in the hole injection material layer HILX does not exceed 3%, the lateral current of the hole injection material layer HILX is reduced. The smaller the mass content of the P-type dopant, the smaller the lateral current of the hole injection material layer HILX. In this way, the hole injection material layer HILX of this embodiment can significantly reduce the lateral current of the hole injection material layer HILX by using a hole-transport-type nitrogen-containing compound on the one hand and reducing the mass content of the P-type dopant on the other hand; this can achieve a balance between improving the hole injection efficiency and reducing crosstalk.

In an embodiment of the present disclosure, referring to FIG. 10, the light-emitting functional layer EFL includes a hole transport material layer HTLX, which covers the gaps between the plurality of light-emitting elements, for example, covers the display area AA. In this way, the hole transport material layer HTLX is a common material layer of the light-emitting functional layer EFL; the portion of the hole transport material layer HTLX in each light-emitting functional unit EFU can serve as the hole transport layer HTL of the light-emitting functional unit EFU. In this embodiment, the hole transport material layer HTLX can include the above-mentioned hole-transport-type nitrogen-containing compound, thereby reducing the lateral resistance of the hole transport material layer HTLX.

For example, in an example, the hole transport material layer HTLX is made of the hole-transport-type nitrogen-containing compound. For another example, the hole transport material layer HTLX includes multiple different and mutually mixed materials, at least one of which is the hole-transport-type nitrogen-containing compound.

In an embodiment of the present disclosure, referring to FIG. 10, at least part of the light-emitting elements LD include a multilayer light-emitting stack structure ELS that is stacked, and the light-emitting functional layer EFL may include a P-type charge generation material layer PCGLX as a common material layer and an N-type charge generation material layer NCGLX as a common material layer. The P-type charge generation material layer PCGLX may cover a plurality of light-emitting elements LD and the gaps between the light-emitting elements LD, for example, the P-type charge generation material layer PCGLX may cover the display area AA; its portion in each light-emitting element LD may serve as the P-type charge generation layer PCGL of the light-emitting element LD. The N-type charge generation material layer NCGLX may cover a plurality of light-emitting elements LD and the gaps between the light-emitting elements LD, for example, it may cover the display area AA; its portion in each light-emitting element LD may serve as the N-type charge generation layer NCGL of the light-emitting element LD.

In an example of this embodiment, the P-type charge generation material layer PCGLX may include the hole-transport-type nitrogen-containing compound described above, which can reduce the lateral current of the P-type charge generation material layer PCGLX and weaken or eliminate the crosstalk between the light-emitting elements LD.

Optionally, the P-type charge generation material layer PCGLX is also doped with a P-type dopant to improve the ability of the P-type charge generation layer PCGL to generate holes. Furthermore, the material of the P-type charge generation material layer PCGLX consists of the hole-transport-type nitrogen-containing compound and the P-type dopant, and the mass content of the P-type dopant is not less than 10%. For example, the material of the P-type charge generation layer PCGL consists of the hole-transport-type nitrogen-containing compound and the P-type dopant, and the mass content of the P-type dopant is between 10% and 15%. In this way, the P-type charge generation material layer PCGLX can have a larger hole generation ability, and the P-type charge generation material layer PCGLX can be prevented from having an excessively large lateral current, achieving a balance between improving luminous efficiency and reducing crosstalk.

In an example, the hole transport material in the P-type charge generation material layer PCGLX is the same as the hole transport material in the hole injection material layer HILX; the P-type dopant in the P-type charge generation material layer PCGLX is the same as the P-type dopant in the hole injection material layer HILX; the only difference is that the mass content of the P-type dopant in the P-type charge generation material layer PCGLX is greater.

In an embodiment of the present disclosure, the material of the N-type charge generation material layer NCGLX consists of an electron transport compound and an N-type dopant; the electron transport compound contains a phenanthroline fragment or a phosphorus oxygen fragment. In this example, the electron transport compound contains a phenanthroline fragment or a phosphorus oxygen fragment, which makes the electron transport compound have a large lateral resistance, which is conducive to reducing the lateral current of the N-type charge generation material layer NCGLX. In this way, the lateral current of the common material layer can be further reduced, and the crosstalk between the light-emitting elements LD can be reduced.

Optionally, the N-type dopant may be a metal material of the first main group, such as lithium.

It can be understood that in some other embodiments of the present disclosure, even if the light-emitting element LD includes a multi-layer light-emitting stack structure ELS, the light-emitting functional layer EFL may not be provided with the P-type charge generation material layer PCGLX or the N-type charge generation material layer NCGLX as common material layers; for example, the P-type charge generation layer PCGL or the N-type charge generation layer NCGL may not be provided in some light-emitting elements LD.

It can be understood that when a part of the light-emitting elements LD of the display panel PNL includes a multi-layer light-emitting stack structure ELS and another part of the light-emitting elements LD includes a single-layer light-emitting stack structure ELS, the light-emitting elements LD including the single-layer light-emitting stack structure ELS may be provided with a charge generation layer CGL or may not be provided with a charge generation layer CGL.

In an embodiment of the present disclosure, the electron transport layer ETL may include an electron transport material, for example, an electron transport material containing an azine fragment, and in particular, an electron transport material containing a triazine fragment. Further, the electron transport layer ETL may be doped with a dopant, for example, the electron transport layer ETL may be doped with Liq (lithium hydroxyquinoline).

In an example, the electron transport material in the electron transport layer ETL may be different from the electron transport material in the N-type charge generation layer NCGL.

In an embodiment of the present disclosure, the hole blocking layer HBL may include an electron transport material, for example, may include an electron transport material containing an azine segment, and in particular, may include an electron transport material containing a triazine segment.

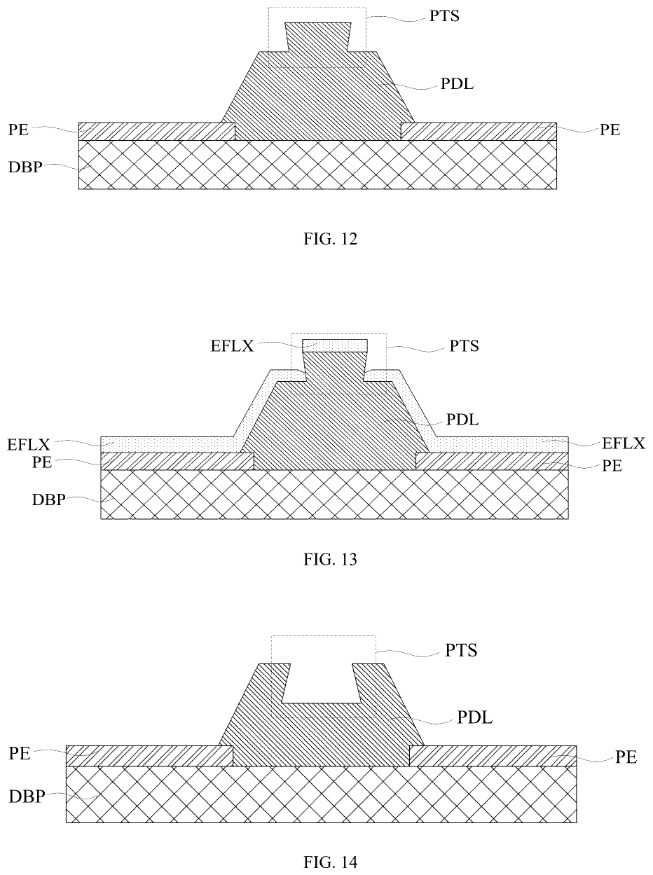

In some embodiments of the present disclosure, referring to FIG. 12 to FIG. 15, the display panel PNL is provided with a partition structure PTS between the light-emitting elements LD; at least one layer of the common material layer EFLX is provided discontinuously at the partition structure PTS. In particular, the partition structure PTS makes at least one of the hole injection material layer HILX, the hole transport material layer HTLX, the P-type charge generation material layer PCGLX and the N-type charge generation material layer NCGLX discontinuous. Furthermore, the partition structure PTS can make the common material layer staggered, that is, different parts of the common material layer at the partition structure PTS can be at different heights. In this way, the partition structure PTS can reduce the width of the lateral current channel between two adjacent light-emitting elements LD, thereby reducing the lateral current between two adjacent light-emitting elements LD.

In some examples, referring to FIG. 12 and FIG. 13, the partition structure PTS may be a convex structure, for example, a convex structure having a larger size at the top (away from the driving backplane DBP) than at the bottom (close to the driving backplane DBP). The portion of the common material layer located above the convex structure is staggered with the portion located outside the convex structure, thereby causing the common material layer EFLX to be discontinuous. For example, the convex structure may be a protrusion with a trapezoidal or T-shaped cross section.

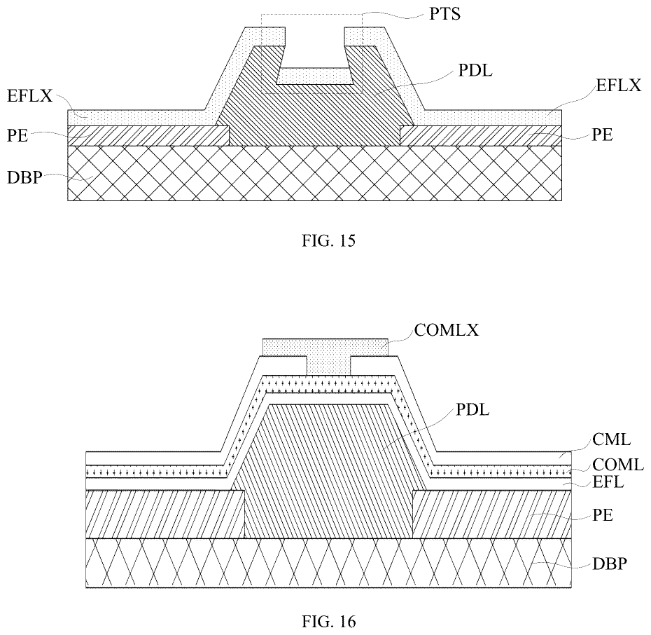

In some examples, referring to FIG. 14 and FIG. 15, the partition structure PTS may be a groove structure, for example, a groove structure in which the groove opening is smaller than the groove bottom. The portion of the common material layer outside the groove structure is staggered with the portion located at the groove bottom, thereby causing the common material layer EFLX to be discontinuous. For example, the groove structure may have a groove with a trapezoidal or T-shaped cross section.

In some examples, the step difference T1 between different parts of the partition structure PTS is not less than the step difference between the light-emitting layer closest to the pixel electrode PE and the pixel electrode PE, for example, the step difference between different parts of the partition structure PTS is greater than 0.5 microns. This can ensure that the common material layer of the light-emitting functional layer EFL, especially the hole injection material layer HILX, is staggered and separated at the partition structure PTS. In the embodiment of the present disclosure, the step difference between different parts of the partition structure PTS refers to the height difference (in the normal direction of the display panel PNL) between the highest point of the partition structure PTS (farthest from the substrate BP) and the lowest point of the partition structure PTS (closest to the substrate BP). For example, when the partition structure PTS is a convex structure, the step difference T1 refers to the height difference between the base surface of the convex structure and the top surface of the convex structure. For another example, when the partition structure PTS is a groove structure, the step difference T1 refers to the height difference between the surface where the groove notch of the groove structure is located and the bottom of the groove.

Optionally, the display panel PNL is provided with a pixel definition layer PDL between the pixel electrode layer PEL and the light-emitting function layer EFL, and the partition structure PTS is provided on the pixel definition layer PDL. In this way, the partition structure PTS can be prepared at the same time as the pixel definition layer PDL is prepared, thereby reducing the number of processes and masks, and reducing the preparation cost of the display panel PNL.

For example, a pixel definition material layer covering the pixel electrode layer PEL may be formed first, and then the pixel definition material layer may be patterned to form a pixel definition layer PDL. The pixel definition layer PDL may have a pixel opening exposing at least a portion of the pixel electrode, and a groove structure as a partition structure PTS; or the pixel definition layer PDL may have a pixel opening exposing at least a portion of the pixel electrode, and a convex structure as a partition structure PTS. Optionally, when patterning the pixel definition material layer, a grayscale mask process may be used to achieve simultaneous preparation of the pixel opening and the partition structure PTS.

In some embodiments of the present disclosure, referring to FIG. 2 and FIG. 3, a partition structure PTS is provided between the red light-emitting element R and the green light-emitting element G. In this way, the lateral current flowing from the green light-emitting element G to the red light-emitting element R can be made smaller, further reducing or eliminating the crosstalk between the red light-emitting element R and the green light-emitting element G. For example, referring to FIG. 2 and FIG. 3, a partition structure PTS is provided between adjacent red light-emitting elements R and green light-emitting elements G. Furthermore, the partition structure PTS can extend in a long strip shape so as to achieve the maximum partition length while reducing the area of the partition structure PTS, and to compress the current channel size of the lateral current between the red light-emitting element R and the green light-emitting element G as much as possible.

In some embodiments of the present disclosure, when a partition structure PTS is provided between two adjacent light-emitting elements LD, the partition structure PTS is in a strip shape; the arrangement square DV of the two adjacent light-emitting elements LD is perpendicular to the extension direction (length direction) of the partition structure PTS. In this way, the partition structure PTS can maximize the isolation effect of the lateral current.

For example, in the example of FIG. 2, the arrangement of sub-pixels on the display panel PNL is SRGB. In this example, the light-emitting elements LD are arranged in a first sub-pixel column and a second sub-pixel column; the first sub-pixel column only includes a plurality of blue light-emitting elements B arranged in sequence along the column square DV; the second sub-pixel column includes red light-emitting elements R and green light-emitting elements G arranged alternately along the column square DV. When a partition structure PTS is provided between adjacent red light-emitting elements R and green light-emitting elements G, the partition structure PTS is in a strip shape and extends along the row direction DH.

Furthermore, the orthographic projections of the red light-emitting element R and the green light-emitting element G in the row direction DH can be located within the orthographic projections of the adjacent partition structure PTS in the row direction DH; this enables the shortest path of the lateral current between the red light-emitting element R and the adjacent green light-emitting element G to be completely isolated by the partition structure PTS, which, on the one hand, can compress the current channel width of the lateral current between the red light-emitting element R and the green light-emitting element G to a greater extent, and on the other hand, greatly extend the current path of the lateral current, thereby further weakening the lateral current between the red light-emitting element R and the green light-emitting element G.

For another example, in the example of FIG. 3, the arrangement of the sub-pixels on the display panel PNL is a diamond arrangement. In this example, each light-emitting element LD can be arranged into a plurality of first sub-pixel groups, each of which includes a plurality of light-emitting elements LD arranged in sequence along the first direction DX. Wherein, the first sub-pixel group includes a first type of first sub-pixel group and a second type of first sub-pixel group arranged side by side and alternately; the first type of first sub-pixel group includes a red light-emitting element R and a green light-emitting element G arranged alternately along the first direction DX, and the second type of first sub-pixel group includes a blue light-emitting element B and a green light-emitting element G arranged alternately along the first direction DX. Each light-emitting element LD can also be arranged into a plurality of second sub-pixel groups, each of which includes a plurality of light-emitting elements LD arranged in sequence along the second direction DY. Wherein, the second sub-pixel group includes a first type of second sub-pixel group and a second type of second sub-pixel group arranged side by side and alternately; the first type of second sub-pixel group includes a red light-emitting element R and a green light-emitting element G arranged alternately along the second direction DY, and the second type of second sub-pixel group includes a blue light-emitting element B and a green light-emitting element G arranged alternately along the second direction DY. In this example, both the first direction DX and the second direction DY are not parallel to the column direction DV and the row direction DH, and the first direction DX and the second direction DY are arranged to intersect.

In the example of FIG. 3, a partition structure PTS is provided between adjacent red light-emitting elements R and green light-emitting elements G. For example, a partition structure PTS is provided between the red light-emitting elements R and the green light-emitting elements G of the first sub-pixel group of the first type, the partition structure PTS is in a strip shape and the extension direction is perpendicular to the first direction DX; a partition structure PTS is provided between the red light-emitting elements R and the green light-emitting elements G of the second sub-pixel group of the first type, the partition structure PTS is in a strip shape and the extension direction is perpendicular to the second direction DY.

In some embodiments of the present disclosure, referring to FIG. 16, the display panel PNL further includes an auxiliary electrode layer COMLX disposed on a side of the common electrode layer COML away from the driving backplane DBP, wherein the auxiliary electrode layer COMLX is electrically connected to the common electrode layer COML and does not overlap with the light-emitting element LD. In this way, the auxiliary electrode layer COMLX can avoid shielding the light-emitting element LD and will not cause a reduction in the brightness of the display panel PNL; it can also be connected in parallel with the common electrode layer COML to reduce the impedance of the common electrode layer COML, improve the uniformity of the common voltage, and help reduce the power consumption of the display panel PNL. In an example, the material of the auxiliary electrode layer COMLX can be a metal or an alloy. Optionally, the auxiliary electrode layer COMLX can be in a grid shape, and each light-emitting element LD is located in the grid opening of the auxiliary electrode layer COMLX. Of course, the auxiliary electrode layer COMLX can also be in other shapes, such as a straight bar or a curved curve.

In an embodiment of the present disclosure, referring to FIG. 16, the display panel PNL is provided with an organic cover layer CML between the common electrode layer COML and the auxiliary electrode layer COMLX; the organic cover layer CML includes a connection via exposing the common electrode layer COML, and the auxiliary electrode layer COMLX is electrically connected to the common electrode layer COML through the connection via. Further, the organic cover layer CML may include at least one of an impedance reduction layer and a light extraction auxiliary layer. Among them, the impedance reduction layer may be a fluorine-containing organic material layer, which may reduce the impedance of the common electrode layer COML. The light extraction auxiliary layer may have a suitable refractive index to facilitate the emission of light emitted by the light-emitting functional unit EFU.

Optionally, referring to FIG. 2 and FIG. 3, the connecting via CNT is located in the gap between the light-emitting elements LD and does not overlap with the partition structure PTS. For example, a connecting via CNT is provided between the red light-emitting element R and the blue light-emitting element B, or a connecting via CNT is provided between the green light-emitting element G and the blue light-emitting element B, or a connecting via CNT is provided between two adjacent blue light-emitting elements B.

Of course, in some other implementations, a patterned impedance reduction layer may also be formed by evaporation through a precision metal mask.

The present disclosure also provides a display apparatus, which includes any one of the display panels described in the above display panel embodiments. The display apparatus can be a smartphone screen, a smart watch screen, or other types of display elements. Since the display apparatus includes any one of the display panels described in the above display panel embodiments, it has the same beneficial effects, and the present disclosure will not be repeated here.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A display panel, comprising a driving backplane, a pixel electrode layer, a light-emitting functional layer, and a common electrode layer stacked in sequence; wherein the light-emitting functional layer comprises a common material layer that covers the gaps between a plurality of light-emitting elements; at least one of the common material layers comprises a hole-transport-type nitrogen-containing compound, the structural formula of which is shown in Chemical Formula 1: 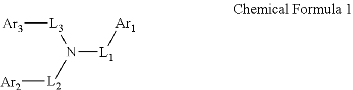
wherein, L₁, L₂, L₃ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
Ar₁ to Ar₃ are each independently selected from a substituted or unsubstituted aryl with 6 to 50 ring carbon atoms, a substituted or unsubstituted heteroaryl with 5 to 40 ring carbon atoms, and —N(Ar₄Ar₅); Ar₄ and Ar₅ are each independently selected from a substituted or unsubstituted aryl with 6 to 50 ring carbon atoms, a substituted or unsubstituted heteroaryl with 5 to 40 ring carbon atoms; wherein at least one of Ar₁ to Ar₃ contains a benzopentacyclic fragment or a dithiophene fragment;
when L₁, L₂, L₃, Ar₁, Ar₂, Ar₃, Ar₄ or Ar₅ has a substituent, the substituent is selected from deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms.

2. The display panel according to claim 1, wherein at least one of Ar₁ to Ar₃ has a group shown in the following Chemical Formula 2 or Chemical Formula 3: 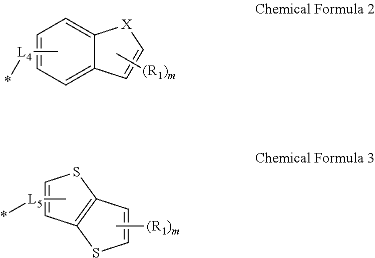
wherein, * indicates connection with L₁, L₂, L₃ or N;
L₄, L₅ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
X is selected from N(R₂), C(R₃R₄), O, S, Si (R₃R₄); m is 0, 1 or 2;
R₁ is selected from the group consisting of deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms;
R₂ to R₄ are each independently selected from a substituted or unsubstituted alkyl with 1 to 10 carbon atoms, a substituted or unsubstituted cycloalkyl with 5 to 10 carbon atoms, a substituted or unsubstituted aryl with 6 to 30 carbon atoms, or a substituted or unsubstituted heteroaryl with 5 to 30 carbon atoms;
when the number of R₁ is two, the two R₁ are connected to each other to form an aromatic ring or an aliphatic ring, or remain unconnected;
R₃ and R₄ are connected to each other to form an aromatic ring or an aliphatic ring, or remain unconnected.

3. The display panel according to claim 1, wherein the L₁, L₂ and L₃ are each independently selected from a single bond, a phenylene, a biphenylene, a terphenylene, a naphthylene, and a trimphenylene;
Ar₁ to Ar₅ are each independently selected from 9,9′-dimethylfluorenyl, spirofluorenyl, benzothiophenyl, N-phenylcarbazolyl, phenyl, biphenyl, 9-phenyl-1,2,3,4-tetrahydrocarbazolyl, phenyl-substituted thieno[3,2-b]thienyl, thieno[3,2-b]thienyl, naphthyl, 9,9′-diphenylfluorenyl, dibenzofuranyl, dibenzothienyl; and at least one of Ar₁ to Ar₃ contains phenyl-substituted thieno[3,2-b]thienyl or thieno[3,2-b]thienyl.

4. The display panel according to claim 1, wherein the hole-transport-type nitrogen-containing compound is selected from the group consisting of the following compounds:

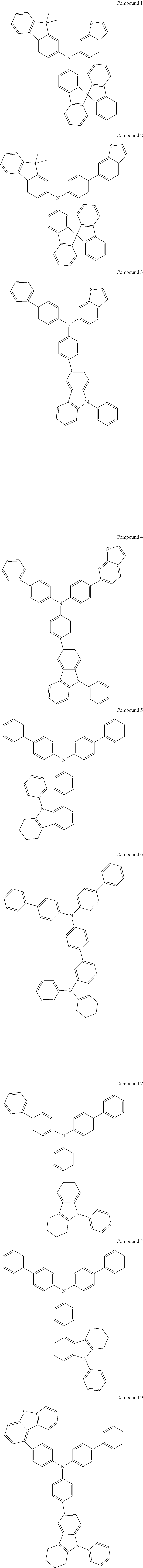

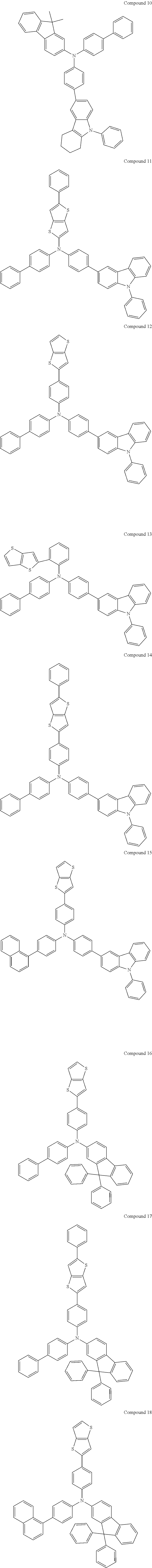

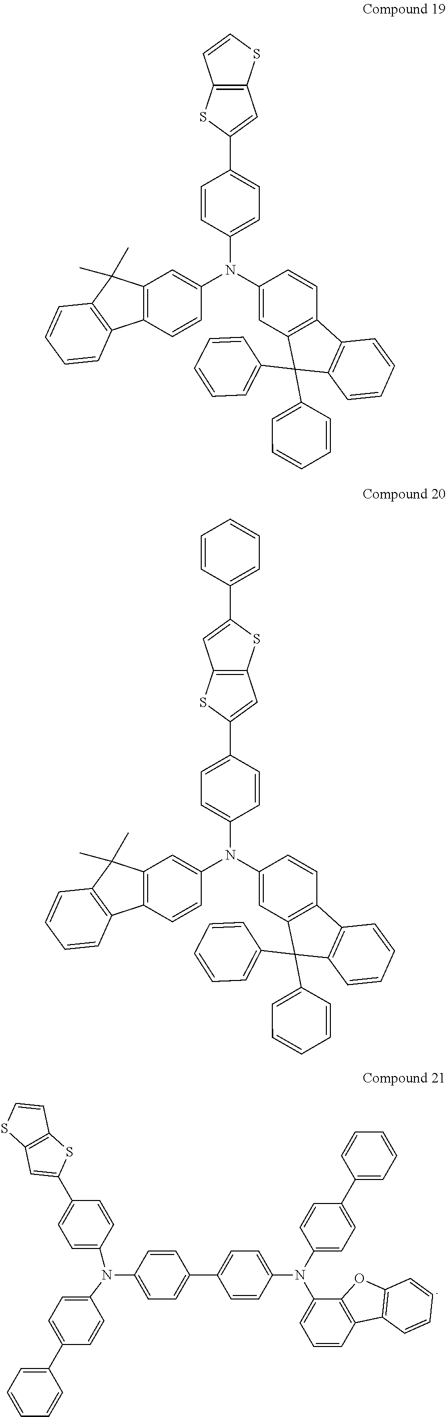 [SMILES: CC1(C)c2ccccc2-c2ccc(N(c3ccc(-c4cc5sccc5s4)cc3)c3ccc4c(c3)C(c3ccccc3)(c3ccccc3)c3ccccc3-4)cc21 ; CC1(C)c2ccccc2-c2ccc(N(c3ccc(-c4cc5sc(-c6ccccc6)cc5s4)cc3)c3ccc4c(c3)C(c3ccccc3)(c3ccccc3)c3ccccc3-4)cc21 ; c1ccc(-c2ccc(N(c3ccc(-c4ccc(N(c5ccc(-c6ccccc6)cc5)c5cccc6c5oc5ccccc56)cc4)cc3)c3ccc(-c4cc5sccc5s4)cc3)cc2)cc1]

5. The display panel according to claim 1, wherein the light-emitting functional layer comprises a hole injection material layer; the hole injection maternal layer covers the gaps between the plurality of light-emitting elements and comprises the hole-transport-type nitrogen-containing compound.

6. The display panel according to claim 5, wherein a material of the hole injection material layer consists of the hole-transport-type nitrogen-containing compound and a P-type dopant, and a mass content of the P-type dopant does not exceed 3%.

7. The display panel according to claim 5, wherein a material of the hole injection material layer consists of the hole-transport-type nitrogen-containing compound and a P-type dopant, and a mass content of the P-type dopant is between 0.5% and 1.5%.

8. The display panel according to claim 1, wherein the light-emitting functional layer comprises a P-type charge generation material layer, which covers the gaps between the plurality of light-emitting elements and comprises the hole-transport-type nitrogen-containing compound.

9. The display panel according to claim 8, wherein a material of the P-type charge generation material layer consists of the hole-transport-type nitrogen-containing compound and a P-type dopant, and a mass content of the P-type dopant is not less than 10%.

10. The display panel according to claim 8, wherein a material of the P-type charge generation material layer consists of the hole-transport-type nitrogen-containing compound and a P-type dopant, and a mass content of the P-type dopant is between 10% and 15%.

11. The display panel according to claim 1, wherein the light-emitting functional layer comprises an N-type charge generation material layer, and the N-type charge generation material layer covers the gaps between the plurality of light-emitting elements; a material of the N-type charge generation material layer consists of an electron transport compound and an N-type dopant; the electron transport compound contains a phenanthroline fragment or a phosphorus oxygen fragment.

12. The display panel according to claim 1, wherein the display panel is provided with a partition structure between the light-emitting elements; and at least one layer of the common material layer is discontinuously provided at the partition structure.

13. The display panel according to claim 12, wherein the display panel is provided with a pixel definition layer between the pixel electrode layer and the light-emitting function layer, and the partition structure is provided in the pixel definition layer.

14. The display panel according to claim 12, wherein the light-emitting element comprises a red light-emitting element, a green light-emitting element and a blue light-emitting element;
the partition structure is arranged between the red light-emitting element and the green light-emitting element.

15. The display panel according to claim 12, wherein the light-emitting functional layer comprises a hole injection material layer covering the gaps between the plurality of light-emitting elements; the hole injection material layer is discontinuously arranged at the partition structure.

16. The display panel according to claim 12, wherein the light-emitting functional layer comprises a charge-generation material layer covering gaps between the plurality of light-emitting elements, and the charge-generation material layer is discontinuously disposed at the partition structure.

17. The display panel according to claim 1, wherein the display panel further comprises an auxiliary electrode layer disposed on a side of the common electrode layer away from the driving backplane, and the auxiliary electrode layer is electrically connected to the common electrode layer and does not overlap with the light-emitting element.

18. The display panel according to claim 17, wherein the display panel is provided with an organic cover layer between the common electrode layer and the auxiliary electrode layer; the organic cover layer comprises a connection via hole exposing the common electrode layer, and the auxiliary electrode layer is electrically connected to the common electrode layer through the connection via hole.

19. A display apparatus, comprising the display panel;
wherein the display panel comprises a driving backplane, a pixel electrode layer, a light-emitting functional layer, and a common electrode layer stacked in sequence; the light-emitting functional layer comprises a common material layer that covers the gaps between a plurality of light-emitting elements; at least one of the common material layers comprises a hole-transport-type nitrogen-containing compound, the structural formula of which is shown in Chemical Formula 1: 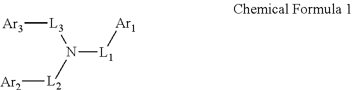
wherein, L₁, L₂, L₃ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
Ar₁ to Ar₃ are each independently selected from a substituted or unsubstituted aryl with 6 to 50 ring carbon atoms, a substituted or unsubstituted heteroaryl with 5 to 40 ring carbon atoms, and —N(Ar₄Ar₅); Ar₄ and Ar₅ are each independently selected from a substituted or unsubstituted aryl with 6 to 50 ring carbon atoms, a substituted or unsubstituted heteroaryl with 5 to 40 ring carbon atoms; wherein at least one of Ar₁ to Ar₃ contains a benzopentacyclic fragment or a dithiophene fragment;
when L₁, L₂, L₃, Ar₁, Ar₂, Ar₃, Ar₄ or Ar₅ has a substituent, the substituent is selected from deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms.

20. The display apparatus according to claim 19, wherein at least one of Ar₁ to Ar₃ has a group shown in the following Chemical Formula 2 or Chemical Formula 3: 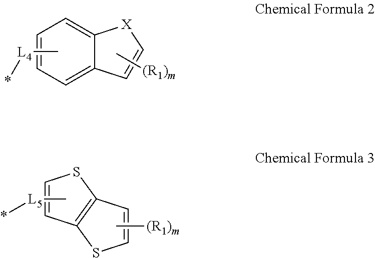
wherein, * indicates connection with L₁, L₂, L₃ or N;
L₄, L₅ are each independently selected from a single bond, a substituted or unsubstituted phenylene, a substituted or unsubstituted biphenylene, a substituted or unsubstituted naphthylene, a substituted or unsubstituted phenanthrenylene, a substituted or unsubstituted triphenylene, a substituted or unsubstituted 9,9′-dimethylfluorenylene, a substituted or unsubstituted 9,9′-diphenylfluorenylene, a substituted or unsubstituted spirofluorenylene, a substituted or unsubstituted carbazolylene;
X is selected from N(R₂), C(R₃R₄), O, S, Si (R₃R₄); m is 0, 1 or 2;
R₁ is selected from the group consisting of deuterium, halogen, substituted or unsubstituted alkyl with 1 to 10 carbon atoms, substituted or unsubstituted cycloalkyl with 5 to 10 carbon atoms, substituted or unsubstituted aryl with 6 to 30 carbon atoms, and substituted or unsubstituted heteroaryl with 5 to 30 carbon atoms;
R₂ to R₄ are each independently selected from a substituted or unsubstituted alkyl with 1 to 10 carbon atoms, a substituted or unsubstituted cycloalkyl with 5 to 10 carbon atoms, a substituted or unsubstituted aryl with 6 to 30 carbon atoms, or a substituted or unsubstituted heteroaryl with 5 to 30 carbon atoms;
when the number of R₁ is two, the two R₁ are connected to each other to form an aromatic ring or an aliphatic ring, or remain unconnected;
R₃ and R₄ are connected to each other to form an aromatic ring or an aliphatic ring, or remain unconnected.
